(19) United States
(12) Patent Application Publication
(10) Pub. No.: US 2023/0352457 A1
(43) Pub. Date: Nov. 2, 2023

(54) DISPLAY PANEL, DISPLAY DEVICE, AND PREPARATION METHOD OF DISPLAY PANEL

(71) Applicant: Tianma Advanced Display Technology Institute (Xiamen) Co., Ltd., Xiamen (CN)

(72) Inventors: Xiaoli LIU, Xiamen (CN); Cao LIU, Xiamen (CN); Haochen QIAN, Xiamen (CN)

(73) Assignee: Tianma Advanced Display Technology Institute (Xiamen) Co., Ltd., Xiamen (CN)

(21) Appl. No.: 18/217,279

(22) Filed: Jun. 30, 2023

(30) Foreign Application Priority Data
Apr. 25, 2023 (CN) 202310457529.5

(51) Int. Cl. H01L 25/075; H01L 25/16; H01L 33/54; H01L 33/44; H01L 33/62; H01L 27/12

(52) U.S. Cl. CPC H01L 25/0753; H01L 25/167; H01L 33/54; H01L 33/44; H01L 33/62; H01L 27/124; H01L 2933/005; H01L 2933/0025

(57) ABSTRACT

Provided are a display panel, a display device and a preparation method of a display panel. The display panel includes an array substrate and a light-emitting unit. The array substrate includes a base substrate and an encapsulation layer located on a side of the base substrate, and a side surface of the encapsulation layer facing away from the base substrate is provided with an accommodation groove. The light-emitting unit is located in the accommodation groove, the accommodation groove is filled with a light-absorbing material, a protective film is formed on both a side surface of the encapsulation layer facing away from the base substrate and a side surface of the light-emitting unit facing away from the base substrate, and an etching rate of the protective film is less than an etching rate of the light-absorbing material under a same etching condition.

### CROSS-REFERENCE TO RELATED APPLICATION

This application claims priority to Chinese Patent Application No. 202310457529.5 filed Apr. 25, 2023, the disclosure of which is incorporated herein by reference in its entirety.

### TECHNICAL FIELD

Embodiments of the present disclosure relate to the field of display technologies, and in particular to, a display panel, a display device, and a preparation method of a display panel.

### BACKGROUND

In existing micro light emitting diode (Micro-LED) technologies and existing mini light emitting diode (mini-LED) technologies, a black light-absorbing material is generally selected for spacing to reduce the reflectivity and improve the halo crosstalk. For a transparent display screen with LEDs, a transparent region and the LEDs are generally encapsulated and protected by using a transparent encapsulation adhesive firstly, and then the black light-absorbing material is manufactured. When the black light-absorbing material is manufactured, a whole layer of black light-absorbing material is generally formed firstly, and then the redundant black light-absorbing material is removed.

However, based on the process fluctuation and the special light emission structure on the surface of the LED, a layer of black material often remains above the transparent region and the LED patterned substrate structure, which affects the transmittance of the transparent region and the light emission efficiency of the LED.

### SUMMARY

The present disclosure provides a display panel, a display device, and a preparation method of a display panel to effectively remove the redundant black light-absorbing material, solve the halo crosstalk, and ensure the transmittance and the display effect of a transparent display screen.

In a first aspect, an embodiment of the present disclosure provides a display panel. The display panel includes an array substrate and a light-emitting unit. The array substrate includes a base substrate and an encapsulation layer located on a side of the base substrate, and a side surface of the encapsulation layer facing away from the base substrate is provided with an accommodation groove. The light-emitting unit is located in the accommodation groove, the accommodation groove is filled with a light-absorbing material, a protective film is formed on both a side surface of the encapsulation layer facing away from the base substrate and a side surface of the light-emitting unit facing away from the base substrate, and an etching rate of the protective film is less than an etching rate of the light-absorbing material under a same etching condition.

In a second aspect, an embodiment of the present disclosure further provides a display device including the display panel as described in the first aspect.

In a third aspect, an embodiment of the present disclosure further provides a preparation method of a display panel. The method includes that: an array substrate is prepared, where the array substrate includes a base substrate and an encapsulation layer located on a side of the base substrate, and a side surface of the encapsulation layer facing away from the base substrate is provided with an accommodation groove; a light-emitting unit is bonded into the accommodation groove; a protective film is formed on both a side surface of the encapsulation layer facing away from the base substrate and a side surface of the light-emitting unit facing away from the base substrate; a light-absorbing material layer is formed on a side surface of the encapsulation layer on which the light-emitting unit is bonded facing away from the base substrate, to enable the accommodation groove to be filled with a light-absorbing material, where an etching rate of the protective film is less than an etching rate of the light-absorbing material under a same etching condition; and the light-absorbing material layer is patterned to remove the light-absorbing material on the side surface of the encapsulation layer facing away from the base substrate and the side surface of the light-emitting unit facing away from the base substrate.

According to the technical schemes of the embodiments of the present disclosure, the array substrate and the light-emitting unit are disposed in the display panel, the array substrate includes the base substrate and the encapsulation layer located on the side of the base substrate, the side surface of the encapsulation layer facing away from the base substrate is provided with the accommodation groove, the light-emitting unit is accommodated in the accommodation groove, and the accommodation groove is filled with the light-absorbing material, so that the transversely emitting light can be absorbed through the light-absorbing material to isolate the light-emitting unit in a transverse direction, thereby avoiding the halo crosstalk between adjacent light-emitting units. Moreover, the protective film is formed on both the side surface of the encapsulation layer facing away from the base substrate and the side surface of the light-emitting unit facing away from the base substrate, and the etching rate of the protective film is less than the etching rate of the light-absorbing material, so it is ensured that the light-absorbing material can be preferentially etched while the redundant light-absorbing material is removed, and the side surface of the covered encapsulation layer and the side surface of the light-emitting unit facing away from the base substrate can be protected and prevented from being etched by the protective film. Thus, the redundant light-absorbing material can be sufficiently removed, the light-shielding effect caused by the residue of the light-absorbing material and the carbonization of the encapsulation layer can be avoided, and the good light emission efficiency of the light-emitting unit and the better light-transmissive effect of the display panel can be ensured.

### BRIEF DESCRIPTION OF DRAWINGS

FIG. 1 is a schematic diagram of a process for removing a light-absorbing layer of an LED transparent display panel in the related art;

FIG. 2 is a structural diagram of a display panel according to an embodiment of the present disclosure;

FIG. 3 is a flowchart of a preparation method of a display panel according to an embodiment of the present disclosure;

FIG. 4 is a structural flowchart of a preparation method of a display panel shown in FIG. 3;

FIG. 5 is a top structural diagram of another display panel according to an embodiment of the present disclosure;

FIG. 6 is a sectional structural diagram of the display panel shown in FIG. 5 taken along direction AA′;

FIG. 7 is a flowchart of another preparation method of a display panel according to an embodiment of the present disclosure;

FIG. 8 is another sectional structural diagram of the display panel shown in FIG. 5 taken along direction AA′;

FIG. 9 is a flowchart of another preparation method of a display panel according to an embodiment of the present disclosure;

FIG. 10 is another sectional structural diagram of the display panel shown in FIG. 5 taken along direction AA′;

FIG. 11 is a top structural diagram of yet another display panel according to an embodiment of the present disclosure;

FIGS. 12 and 13 are sectional structural diagrams of the display panel shown in FIG. 11 taken along directions EE′ and FF′, respectively;

FIG. 14 is another sectional structural diagram of the display panel shown in FIG. 5 taken along direction AA′;

FIG. 15 is a sectional structural diagram of the display panel shown in FIG. 5 taken along direction BB′;

FIGS. 16 and 17 are two sectional structural diagrams of the display panel shown in FIG. 5 taken along direction AA′;

FIGS. 18 and 19 are two sectional structural diagrams of the display panel shown in FIG. 5 taken along direction CC′;

FIG. 20 is a sectional structural diagram of the display panel shown in FIG. 5 taken along direction DD′;

FIGS. 21 and 22 are partial sectional structural diagrams of two other display panels according to an embodiment of the present disclosure;

FIGS. 23, 24 and 25 are partial sectional structural diagrams of three other display panels according to an embodiment of the present disclosure;

FIGS. 26 and 27 are partial sectional structural diagrams of two other display panels according to an embodiment of the present disclosure;

FIG. 28 is a partial sectional structural diagram of another display panel according to an embodiment of the present disclosure; and

FIG. 29 is a structural diagram of a display device according to an embodiment of the present disclosure.

### DETAILED DESCRIPTION

The present disclosure will be further described in detail in conjunction with the drawings and embodiments below. It should be understood that the specific embodiments described herein are merely used for explaining the present disclosure and are not intended to limit the present disclosure. In addition, it should also be noted that, for ease of description, only some, but not all, of the structures related to the present disclosure are shown in the drawings.

Terms used in the embodiments of the present disclosure are merely used for describing specific embodiments and are not intended to limit the present disclosure. It should be noted that the nouns of locality such as “on”, “below”, “left” and “right” described in the embodiments of the present disclosure are described from the perspective of the drawings, and should not be understood as limiting the embodiments of the present disclosure. In addition, in this context, it should also be understood that when an element is formed “on” or “below” another element, it may not only be directly formed “on” or “below” another element, and may also be indirectly formed “on” or “below” another element through an intervening element. The terms “first”, “second” and the like are used for description only, and do not represent any order, quantity, or importance, but only used for distinguishing different components. For those of ordinary skilled in the art, the specific meanings of the above terms in the present disclosure may be understood according to specific situations.

The term “including” and variations thereof as used in the present disclosure is intended to be open-ended, that is, “including but not limited to”. The term “based on” is “based at least in part on”. The term “one embodiment” denotes “at least one embodiment”.

It should be noted that the concepts of “first”, “second” and the like mentioned in the present disclosure are only used to distinguish the corresponding contents, and are not used to limit the order or interdependencies.

It should be noted that the modifications of “one” or “multiple” mentioned in the present disclosure are intended to be illustrative rather than limiting, and it should be understood by those skilled in the art that the modifications of “one” or “multiple” mentioned in the present disclosure, unless the context clearly dictates otherwise, should be understood as “one or more”.

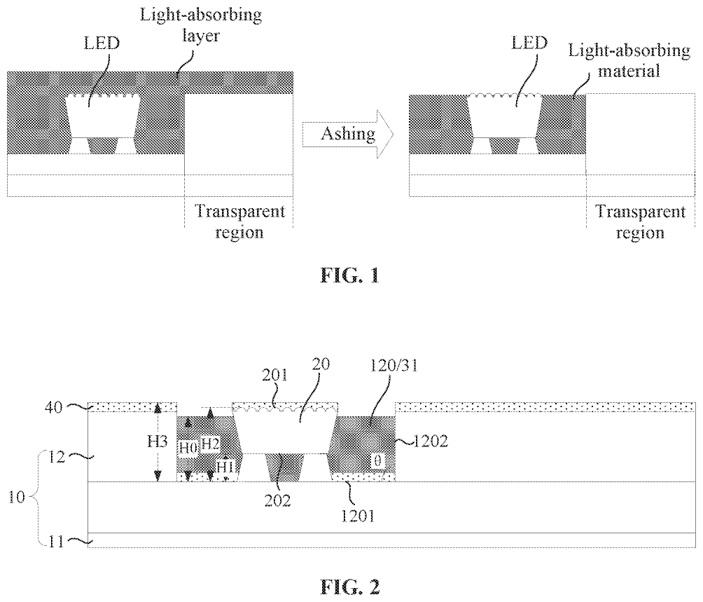

FIG. 1 is a schematic diagram of a process for removing a light-absorbing layer of an LED transparent display panel in the related art. Referring to FIG. 1, as described in the background, a whole layer of a black light-absorbing layer is formed in an existing LED transparent display panel and covers both the LED and a transparent region, and an insulation for the LED is further formed by removing the black light-absorbing material in the redundant region. Specifically, the black light-absorbing material of the LED light emission side and the transparent region is removed by an ashing process. However, there are the following problems in this process: 1) the black light-absorbing material remains on the concavo-convex patterned surface of the LED light emission side surface, resulting in a decrease in the LED light emission efficiency; 2) the black light-absorbing material is easy to remain on the surface of the encapsulation adhesive of the transparent region, and the remaining black light-absorbing material absorbs the light passing through the transparent region to some extent, resulting in a decrease in the transmittance of the transparent region; 3) when the remaining black light-absorbing material is removed by the ashing process, the difference in the materials of different film layers results in a large difference in the selection ratio of the ashing etching, so that the encapsulation adhesive in the transparent region is preferentially carbonized during the ashing process, which also affects the transmittance and stability of the encapsulation adhesive to some extent.

In view of the above-described technical problems, an embodiment of the present disclosure provides a display panel. The display panel includes an array substrate and a light-emitting unit. The array substrate includes a base substrate and an encapsulation layer located on a side of the base substrate, and a side surface of the encapsulation layer facing away from the base substrate is provided with an accommodation groove. The light-emitting unit is located in the accommodation groove, the accommodation groove is filled with a light-absorbing material, a protective film is formed on both a side surface of the encapsulation layer facing away from the base substrate and a side surface of the light-emitting unit facing away from the base substrate, and an etching rate of the protective film is less than an etching rate of the light-absorbing material under a same etching condition.

In the above-described technical schemes, the array substrate and the light-emitting unit are disposed in the display panel, the array substrate includes the base substrate and the encapsulation layer located on the side of the base substrate, the side surface of the encapsulation layer facing away from the base substrate is provided with the accommodation groove, the light-emitting unit is accommodated in the accommodation groove, and the accommodation groove is filled with the light-absorbing material, so that the transversely emitting light can be absorbed through the light-absorbing material to isolate the light-emitting unit in a transverse direction, thereby avoiding the halo crosstalk between adjacent light-emitting units. Moreover, the protective film is formed on both the side surface of the encapsulation layer facing away from the base substrate and the side surface of the light-emitting unit facing away from the base substrate, and the etching rate of the protective film is less than the etching rate of the light-absorbing material, so it is ensured that the light-absorbing material can be preferentially etched while the redundant light-absorbing material is removed, and the side surface of the covered encapsulation layer and the side surface of the light-emitting unit facing away from the base substrate can be protected and prevented from being etched by the protective film. Thus, the redundant light-absorbing material can be sufficiently removed, the light-shielding effect caused by the residue of the light-absorbing material and the carbonization of the encapsulation layer can be avoided, and the good light emission efficiency of the light-emitting unit and the better light-transmissive effect of the display panel can be ensured.

The above is the core idea of the present disclosure, and the technical schemes of the embodiments of the present disclosure will be described clearly and completely in connection with the drawings in the embodiments of the present disclosure below. All other embodiments obtained by those skilled in the art based on the embodiments of the present disclosure without requiring creative efforts shall all fall in the scope of protection of the present disclosure.

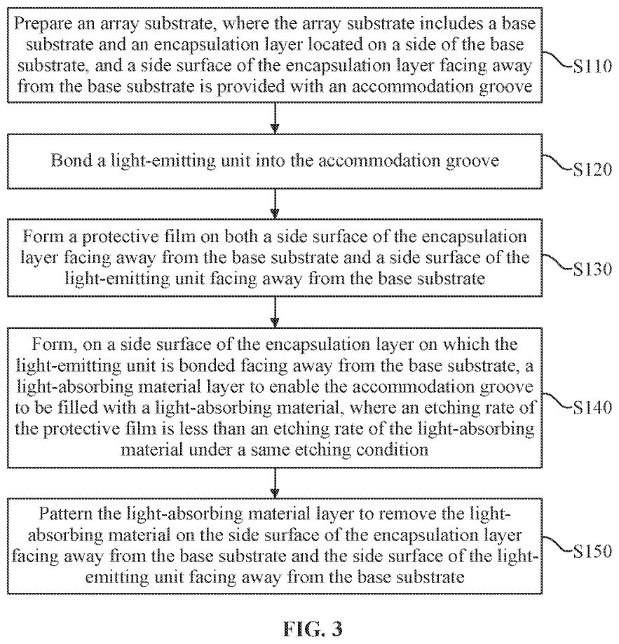

FIG. 2 is a structural diagram of a display panel according to an embodiment of the present disclosure. Referring to FIG. 2, the display panel includes an array substrate 10 and a light-emitting unit 20. The array substrate 10 includes a base substrate 11 and an encapsulation layer 12 located on a side of the base substrate, and a side surface of the encapsulation layer 12 facing away from the base substrate 11 is provided with an accommodation groove 120. The light-emitting unit 20 is located in the accommodation groove 120, the accommodation groove 120 is filled with a light-absorbing material 31, a protective film 40 is formed on both a side surface of the encapsulation layer 12 facing away from the base substrate 11 and a side surface of the light-emitting unit 20 facing away from the base substrate 11, and an etching rate of the protective film 40 is less than an etching rate of the light-absorbing material 31 under a same etching condition.

The base substrate 11 may be a rigid substrate, a flexible substrate, a transparent substrate, or a non-transparent substrate. Exemplarily, the base substrate 11 may be a glass substrate. It should be understood by those skilled in the art that a driver circuit structure (not shown in the drawings) may be disposed in the array substrate 10 to drive the light-emitting unit to emit light and further achieve the picture display, while the encapsulation layer 12 formed on a side surface of the base substrate 11 in the embodiments of the present disclosure refers to the concept of encapsulation for the driver circuit structure in the array substrate 10, rather than the concept of encapsulation for the light-emitting unit 20. The encapsulation layer 12 may be prepared by using a transparent organic resin material such as acrylic, epoxy resin, or silicone resin, and a surface of the encapsulating layer 12 may be trenched to form the accommodation groove 120 for accommodating the light-emitting unit 20 after being cured. The accommodation groove 120 functions to accommodate and protect the light-emitting unit 20 on the one hand, and also functions to expose the electrode structure of the driver circuit structure in the array substrate 10 on the other hand, so as to electrically connect the light-emitting unit 20 to the driver circuit structure.

In addition, it should also be noted that the accommodating and protecting function of the accommodation groove 120 is mainly embodied in that the accommodation groove 120 is filled with the light-absorbing material 31, the light-absorbing material 31 may be specifically prepared by using acrylic, epoxy resin, silicone resin mixed with carbon black or black pigment, which appears black, gray or gray-black. The light-absorbing material 31 may fix the light-emitting unit 20 in the accommodation groove 120 after being cured, so as to fix and protect the light-emitting unit 20. Of course, the accommodation groove 120 and the light-absorbing material 31 also function mainly to wrap a side surface of the light-emitting unit in a direction parallel to a plane of the base substrate 11, absorb and shield the light emitted from the light-emitting unit 20 in the transverse direction, and prevent the light-emitting unit 20 from generating halos in the transverse direction to result in the mutual crosstalk.

In addition to the above-described structures, in the display panel of the embodiments of the present disclosure, the protective film 40 is formed on both the side surface of the encapsulation layer 12 facing away from the base substrate 11 and the side surface of the light-emitting unit 20 facing away from the base substrate 11, i.e., an upper surface shown in FIG. 2, the protective film 40 is made of a material with an etching rate less than an etching rate of the light-absorbing material 31, so that the protective film 40 can protect the encapsulation layer 12 and the light-emitting unit 20. The specific principle thereof relates to the preparation process of the protective film 40 and the light-absorbing material 31. The preparation method of the display panel and the protection principle of the protective film 40 are described below with respect to the above-described structure.

Firstly, it should be noted that the etching rate of the protective film 40 being less than the etching rate of the light-absorbing material 31 under the same etching condition essentially means that a ratio of the etching rate of the protective film 40 to the etching rate of the light-absorbing material 31 is less than 1, and that the relative etching rate of the protective film to the light-absorbing material 31 is slow under the same etching condition. Optionally, the protective film 40 may be an inorganic material, for example, one or more layers of inorganic materials such as silicon nitride or silicon oxide, and the light-absorbing material may be an organic material. Since the inorganic material is denser than the organic material, the inorganic protective film 40 may have a lower etching rate than the organic light-absorbing material 31. In addition, optionally, the protective film 40 and the light-absorbing material 31 are both organic materials. Further, the thickness of the protective film 40 is less than the thickness of the light-absorbing material 31.

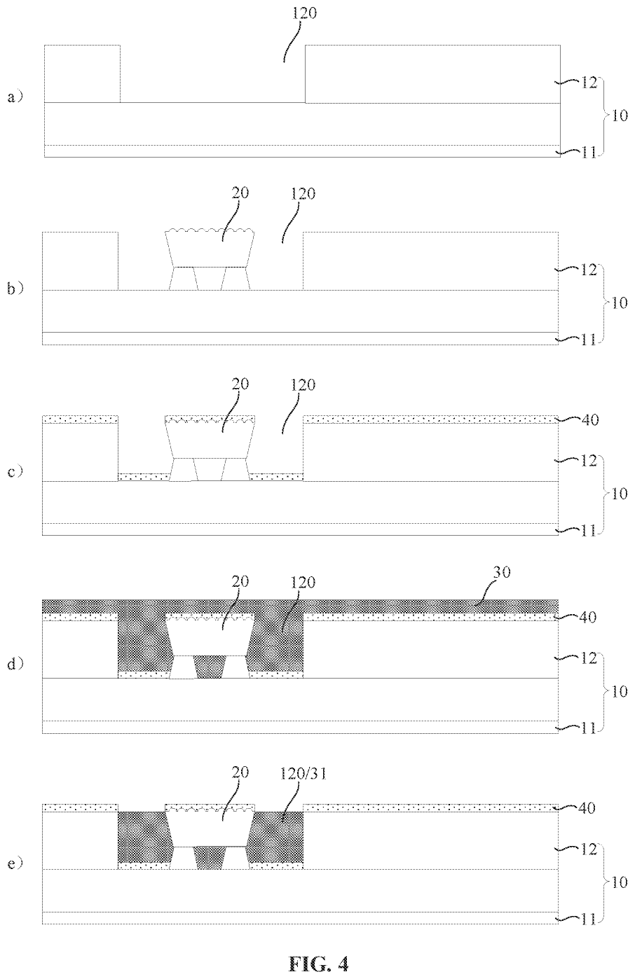

FIG. 3 is a flowchart of a preparation method of a display panel according to an embodiment of the present disclosure. FIG. 4 is a structural flowchart of a preparation method of a display panel shown in FIG. 3. Referring to FIGS. 2 to 4, the preparation method of the display panel includes steps described below.

In S110, an array substrate is prepared, where the array substrate includes a base substrate and an encapsulation layer located on a side of the base substrate, and a side surface of the encapsulation layer facing away from the base substrate is provided with an accommodation groove.

Referring to the diagram a) of FIG. 4, a side surface of the encapsulation layer 12 facing away from the base substrate 11 is provided with an accommodation groove 120 for exposing electrodes (not shown) in a driver circuit structure in the array substrate 10.

In S120, a light-emitting unit is bonded into the accommodation groove.

Referring to the diagram b) of FIG. 4, this process is a process in which light-emitting units 20 are disposed in accommodation grooves 120 in a one-to-one correspondence and an electrode of the light-emitting unit 20 is bonded to the exposed electrode in the accommodation groove 120. A certain alignment precision is required in this process to ensure that the light-emitting unit 20 is aligned with and bonded to the exposed electrode in the accommodation groove 120, avoiding the poor contact.

In S130, a protective film is formed on both a side surface of the encapsulation layer facing away from the base substrate and a side surface of the light-emitting unit facing away from the base substrate.

Referring to the diagram c) of FIG. 4, the protective film 40 in this process may be exemplarily prepared by using a transparent inorganic material such as silicon dioxide, silicon nitride, or silicon oxynitride, that is, the protective film 40 may be optionally an inorganic protective film. Based on this, the step is specifically as follows: an inorganic protective film is formed on the side surface of the encapsulation layer facing away from the base substrate and the side surface of the light-emitting unit facing away from the base substrate by using the inorganic material. In the process of preparing the inorganic material in this step, the inorganic material may be specifically prepared by using existing deposition technologies such as vapor deposition, which is not limited herein. It should also be noted that, since the accommodation space of the accommodation groove 120 is generally set to be greater than the volume of the light-emitting unit 20, that is, a certain gap exists between the light-emitting unit 20 and a side wall of the accommodation groove 120, when the protective film 40 is prepared, a part of the protective film 40 is also formed in a gap between the accommodation groove 120 and the light-emitting unit 20.

In S140, a light-absorbing material layer is formed on a side surface of the encapsulation layer on which the light-emitting unit is bonded facing away from the base substrate, to enable the accommodation groove to be filled with the light-absorbing material, where an etching rate of the protective film is less than an etching rate of the light-absorbing material under a same etching condition.

Referring to the diagram d) of FIG. 4, as described above, the light-absorbing material layer 30 may be prepared by using acrylic, epoxy resin, silicone resin mixed with carbon black or black pigment. In the specific process of step S140, a liquid light-absorbing material is coated on the encapsulation layer 12 and an upper surface of the light-emitting unit 20, and the light-absorbing material flows into the accommodation groove 120 and the accommodation groove 120 is filled with the light-absorbing material due to the fluidity of the liquid. Then, the light-absorbing material is subjected to a curing operation. It should be understood that the light-absorbing material remaining on the encapsulation layer 12 and the light-emitting unit 20 in this step is a redundant structure and needs to be subsequently removed.

In S150, the light-absorbing material layer is patterned to remove the light-absorbing material on the side surface of the encapsulation layer facing away from the base substrate and the side surface of the light-emitting unit facing away from the base substrate.

Referring to the diagram e) of FIG. 4, in the process of patterning the light-absorbing material layer 30, i.e., the process of removing the light-absorbing material on the encapsulation layer 12 and the light-absorbing material on the light-emitting unit 20, the light-absorbing material on the encapsulation layer 12 and the light-absorbing material on the light-emitting unit are generally removed by using a mask plate and using an ashing etching process. It should be understood that compared to the structure of an existing display panel, in the embodiment of the present disclosure, since the protective film 40 is formed on the encapsulation layer 12 and the light-emitting unit 20, a selective etching of the protective film 40 is relatively low, and a ratio of the selective etching of the protective film 40 to a selective etching of the light-absorbing material is less than 1, and the etching rate of the protective film 40 is lower under a same etching condition. Therefore, in the ashing etching process of the light-absorbing material layer 30, even if the light-absorbing material on the encapsulation layer 12 and the light-absorbing material the light-emitting unit 20 are completely removed, the exposed protective film 40 is relatively difficult to be etched, so that the encapsulation layer 12 and the light-emitting unit 20 can be prevented from being etched in this process, thereby achieving the protection of the encapsulation layer 12 and the light-emitting unit 20. In addition, since the encapsulation layer 12 and the light-emitting unit 20 can be prevented from being etched even if the protective film 40 is exposed, the etching process may be designed to sufficiently remove the redundant light-absorbing material and prevent the light-absorbing material from remaining on the encapsulation layer 12 and the light-emitting unit 20.

In summary, according to the schemes of the embodiments of the present disclosure, the problems of poor light emission efficiency and low transmittance caused by remaining light-absorbing material in the existing display panel can be solved, and the light-emitting unit may be isolated in the transverse direction not only by means of absorbing the light emitted in the transverse direction by the light-absorbing material, thereby avoiding the halo crosstalk between adjacent light-emitting units. Moreover, it can be ensured that the light-absorbing material may be preferentially etched while the redundant light-absorbing material is removed, the side surface of the covered encapsulation layer and the light-emitting unit facing away from the base substrate can be protected and prevented from being etched by the protective film. Thus, the redundant light-absorbing material can be sufficiently removed, the light-shielding effect caused by the residue of the light-absorbing material and the carbonization of the encapsulation layer can be avoided, and the good light emission efficiency of the light-emitting unit and the better light-transmissive effect of the display panel can be ensured.

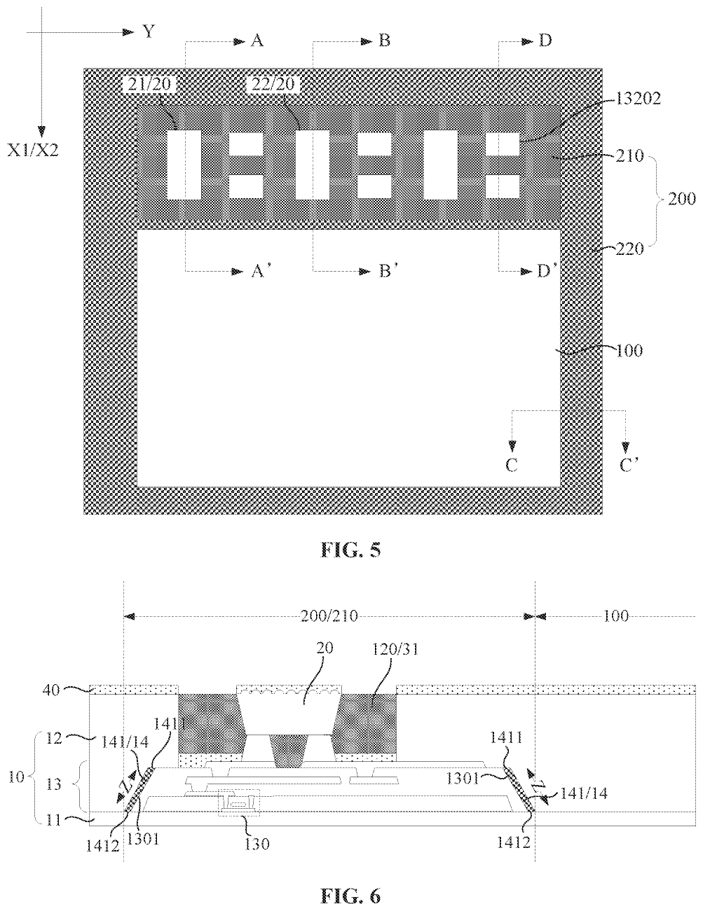

On the basis of the above embodiments, the present disclosure further provides a display panel. FIG. 5 is a top structural diagram of another display panel according to an embodiment of the present disclosure. FIG. 6 is a sectional structural diagram of the display panel shown in FIG. 5 taken along direction AA′. Referring to FIGS. 5 and 6, in the display panel of this embodiment, an array substrate 10 includes a light-transmissive region 100 and a light-nontransmissive region 200, and the light-nontransmissive region 200 includes a driver circuit region 210. The array substrate 10 further includes a thin film transistor (TFT) array layer 13 located between a base substrate 11 and an encapsulation layer 12, the TFT array layer 13 in the driver circuit region 210 includes a drive transistor 130, and the TFT array layer 13 in the driver circuit region 210 includes a height drop in a direction perpendicular to the base substrate and forms a first side wall 1301. A light-shielding structure 14 is disposed in the array substrate 10, the light-shielding structure 14 includes a first light-shielding segment 141, and the first light-shielding segment 141 covers at least a part of the first side wall 1301 of the TFT array layer 13.

First, the TFT array layer 13 in the array substrate 10 is a film layer for forming a driver circuit as described above, and the TFT array layer 13 generally includes a semiconductor layer, a multilayer metal layer, an interlayer insulating layer between metal layers, and the like. The drive transistor 130 may be formed of these film layer structures. The drive transistor 130 is responsible for controlling the lighting of a light-emitting unit 20, and the specific driving process thereof is known to those skilled in the art and will not be described herein. It should be noted that, in this embodiment, the display panel is substantially a transparent display panel, and the light-transmissive region 100 and the light-nontransmissive region 200 disposed on the array substrate 10 are mainly dependent on the position of the driver circuit. It should be understood that the driver circuit is generally a light-nontransmissive structure, and a region where the drive circuit is located is the light-nontransmissive region 200. In order to ensure the light transmission of the display panel, it is necessary to simultaneously dispose the light-transmissive region 100 in the array substrate 10 for light transmission, thereby ensuring that the display effect and the light-transmissive effect can be macroscopically presented at the same time.

In comparison with the light-transmissive region 100, the driver circuit is disposed in the light-nontransmissive region 200, that is, the driver circuit region 210 is formed. In a region of the transition or interface between the driver circuit region 210 and the light-transmissive region 100, the TFT array layer 13 has a height drop due to a certain thickness, that is, the first side wall 1301 is formed. In this embodiment, the light-shielding structure 14 is further disposed in the array substrate 10, and the light-shielding structure 14 may also be prepared by using acrylic, epoxy resin, silicone resin mixed with carbon black or black pigment, which appears black or gray. The first light-shielding segment 141 in the light-shielding structure 14 is covered on the first side wall 1301, and the first light-shielding segment 141 can prevent the external light, particularly light from the light-transmissive region 100, from being incident to the TFT array layer 13 in the transverse direction to a certain extent, whereby the drive transistor 130 in the TFT array layer is prevented from being irradiated by light to generate a change in photoelectric characteristics, which affects the driving stability thereof and generates a leakage current to affect the driving of the light-emitting unit 20.

Further, with continued reference to FIG. 6, optionally, the first light-shielding segment 141 includes a first side edge 1411 and a second side edge 1412 away from each other in a first direction Z, and the first direction Z is perpendicular to an edge line of a side of the driver circuit region 210 facing towards the light-transmissive region 100 and is parallel to a plane where the first side wall 1301 of the TFT array layer 13 is located. The edge line of the side of the driver circuit region 210 facing towards the light-transmissive region 100 is a line perpendicular to the section of the display panel taken along direction AA′. The first side edge 1411 extends to a side surface of the TFT array layer 13 facing away from the base substrate 11, and the second side edge 1412 extends to the base substrate 11. At this time, the first light-shielding segment 141 can ensure that the entire first side wall 1301 is covered, whereby the light incident to the TFT array layer 13 in the transverse direction is effectively blocked, and the electrical properties of the drive transistor therein is prevented from being disturbed. It needs to be supplemented that, since the base substrate 11 is generally prepared by using a transparent glass substrate, in order to prevent the electrical properties of the drive transistor 130 from being affected due to the light incident from a side of the base substrate 11 to the inside the TFT array layer 13, a metal light-shielding structure (not shown in the drawings) is generally disposed between the base substrate 11 and the TFT array layer 13, and a projection of the drive transistor 130 in the plane where the base substrate 11 is located in a projection of the metal light-shielding structure in the plane where the base substrate 11 is located, so that the light incident on a side of the base substrate 11 is shielded by using the metal light-shielding structure.

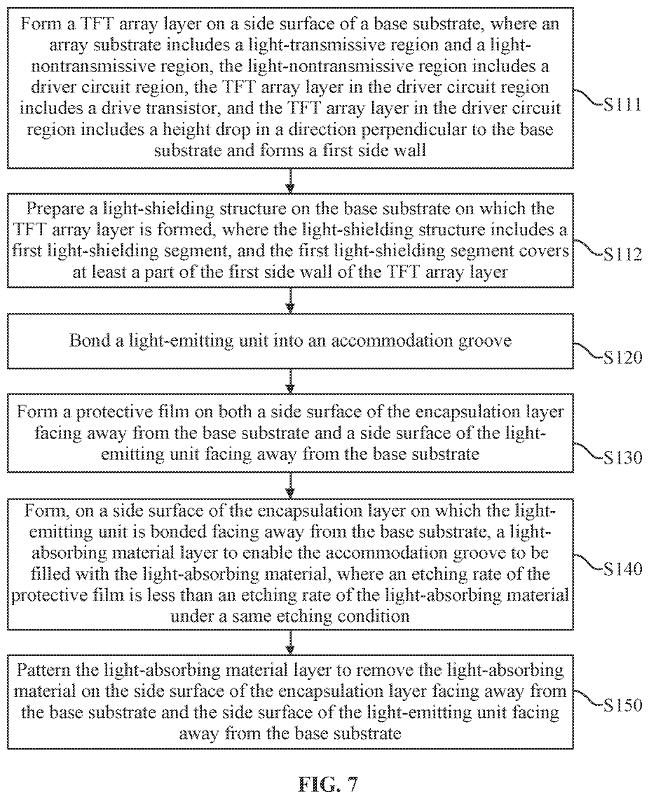

Of course, the present disclosure further provides a corresponding preparation method of the display panel provided with the light-shielding structure. FIG. 7 is a flowchart of another preparation method of a display panel according to an embodiment of the present disclosure. Referring to FIG. 7, the preparation method of the display panel is refined with respect to the above-described step S110, and the step in which the array substrate is prepared may include that: a TFT array layer is formed on a side surface of a base substrate, where an array substrate includes a light-transmissive region and a light-nontransmissive region, the light-nontransmissive region includes a driver circuit region, the TFT array layer in the driver circuit region includes a drive transistor, and the TFT array layer in the driver circuit region includes a height drop in a direction perpendicular to the base substrate and forms a first side wall; and a light-shielding structure is prepared on the base substrate on which the TFT array layer is formed, where the light-shielding structure includes a first light-shielding segment, and the first light-shielding segment covers at least a part of the first side wall of the TFT array layer.

Specifically, the preparation method of the display panel shown in FIGS. 5 and 6 may include steps described below.

In S111, a TFT array layer is formed on a side surface of a base substrate, where an array substrate includes a light-transmissive region and a light-nontransmissive region, the light-nontransmissive region includes a driver circuit region, the TFT array layer in the driver circuit region includes a drive transistor, and the TFT array layer in the driver circuit region includes a height drop in a direction perpendicular to the base substrate and forms a first side wall.

In S112, a light-shielding structure is prepared on the base substrate on which the TFT array layer is formed, where the light-shielding structure includes a first light-shielding segment, and the first light-shielding segment covers at least a part of the first side wall of the TFT array layer.

In S120, a light-emitting unit is bonded into an accommodation groove.

In S130, a protective film is formed on both a side surface of the encapsulation layer facing away from the base substrate and a side surface of the light-emitting unit facing away from the base substrate.

In S140, a light-absorbing material layer is formed on a side surface of the encapsulation layer on which the light-emitting unit is bonded facing away from the base substrate, to enable the accommodation groove to be filled with a light-absorbing material, where an etching rate of the protective film is less than an etching rate of the light-absorbing material under a same etching condition.

In S150, the light-absorbing material layer is patterned to remove the light-absorbing material on the side surface of the encapsulation layer facing away from the base substrate and the side surface of the light-emitting unit facing away from the base substrate.

For the content of the preparation method in this embodiment that has not been detailed, reference is made to the previous embodiment, which will not be described in detail herein.

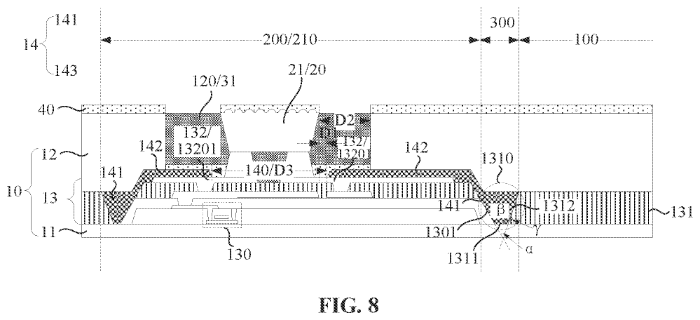

FIG. 8 is another sectional structural diagram of the display panel shown in FIG. 5 taken along direction AA′. Referring to FIG. 8, in the display panel of this embodiment, the TFT array layer 13 includes a planarization layer 131, and a groove 1310 is formed on a side surface of the planarization layer 131 facing away from the base substrate 11. The array substrate 10 further includes a transition region 300 located between the driver circuit region 210 and the light-transmissive region 100, and a projection of the groove 1310 on a plane where the base substrate 11 is located is located in the transition region 300. The first side wall 1301 of the TFT array layer 13 is also used as an inner wall of the groove 1310, and the groove 1310 is filled with a part of the first light-shielding segment 141.

The transition region 300 refers to a region where the driver circuit region 210 and the light-transmissive region 100 are interfaced. Since the light-shielding structure such as the first light-shielding segment 141 extends from the driver circuit region 210 to the light-transmissive region 100, a light-nontransmissive and light-transmissive transition region may be formed between the driver circuit region 210 and the light-transmissive region 100. The planarization layer 131 disposed in the TFT array layer 13 in this embodiment is mainly used for planarizing film layers with a height drop in the TFT array layer 13, whereby the planarizing of a side surface (i.e., an upper surface) of the TFT array layer 13 facing away from the base substrate 11, is ensured so as to form a flat drive electrode to bond the light-emitting unit 20. The thickness of the planarization layer 131 may be generally set to 1 μm to 8 μm. Based on the arrangement of the planarization layer 131, in this embodiment, it is essential that the groove 1310 is formed by trenching the planarization layer 131 of the transition region 300, in other words, the projection of the groove 1310 in the plane where the base substrate 11 is located falls within the transition region 300. The provision of the groove 1310 serves two following purposes. On the one hand, an artificial fracture region is created for the planarization layer 131 by the groove 1310, where the stress may be released at this groove 1310 so as to avoid the warpage of the panel due to the stress formed after the entire planarization layer 131 is cured; on the other hand, the inner wall of the groove 1310 is also used as the first side wall 1301 of the TFT array layer 13, and when the first light-shielding segment 141 is formed, the groove 1310 may be used for accommodating the redundant light-shielding material while ensuring that the light-shielding material is attached to the first side wall 1301, thereby achieving the transverse light-shielding of the TFT array layer 13.

Similarly, an embodiment of the present disclosure further provides a corresponding preparation method. FIG. 9 is a flowchart of another preparation method of a display panel according to an embodiment of the present disclosure. Referring to FIGS. 8 and 9, in this preparation method, the following steps are added before the above-described step S111: a side surface of the planarization layer facing away from the base substrate is provided with a groove, where the array substrate further includes a transition region located between the driver circuit region and the light-transmissive region, a projection of the groove on a plane where the base substrate is located is located in the transition region, and the first side wall of the TFT array layer is also used as an inner wall of the groove.

Correspondingly, the above-described step S112 may be refined as follows: the light-absorbing material is coated on the base substrate on which the TFT array layer is formed, and the groove is filled with at least a part of the light-absorbing material; and the light-absorbing material is cured to form the first light-shielding segment, where the groove is filled with a part of the first light-shielding segment.

Specifically, the preparation method of the display panel shown in FIGS. 8 and 9 may include steps described below.

In S1101, a groove is formed on a side surface of the planarization layer facing away from the base substrate, where the array substrate further includes a transition region located between the driver circuit region and the light-transmissive region, a projection of the groove on a plane where the base substrate is located is located in the transition region, and the first side wall of the TFT array layer is also used as an inner wall of the groove.

In S111, a TFT array layer is formed on a side surface of the base substrate, where the array substrate includes a light-transmissive region and a light-nontransmissive region, the light-nontransmissive region includes a driver circuit region, the TFT array layer in the driver circuit region includes a drive transistor, and the TFT array layer in the driver circuit region includes a height drop in a direction perpendicular to the base substrate and forms a first side wall.

In S1121, the light-absorbing material is coated on the base substrate on which the TFT array layer is formed, and the groove is filled with at least a part of the light-absorbing material.

In S1122, the light-absorbing material is cured to form the first light-shielding segment, where the groove is filled with a part of the first light-shielding segment.

In S120, a light-emitting unit is bonded into the accommodation groove.

In S130, a protective film is formed on both a side surface of the encapsulation layer facing away from the base substrate and a side surface of the light-emitting unit facing away from the base substrate.

In S140, a light-absorbing material layer is formed on a side surface of the encapsulation layer on which the light-emitting unit is bonded facing away from the base substrate, to enable the accommodation groove to be filled with the light-absorbing material, where an etching rate of the protective film is less than an etching rate of the light-absorbing material under a same etching condition.

In S150, the light-absorbing material layer is patterned to remove the light-absorbing material on the side surface of the encapsulation layer facing away from the base substrate and the side surface of the light-emitting unit facing away from the base substrate.

For the content of the preparation method in this embodiment that has not been detailed, reference is made to the previous embodiment, which will not be described in detail herein.

With continued reference to FIG. 8, in a specific embodiment, optionally, the groove 1310 penetrates through the planarization layer 131, and a surface of the base substrate 11 is used as a bottom of the groove, and the groove 1310 is filled with a part of the first light-shielding segment 141, and the part of the first light-shielding segment 141 is in contact with the surface of the base substrate 11. At this time, the groove 1310 can better release the stress of the planarization layer 131, while also ensure that the first light-shielding segment 141 completely covers the first side wall 1301 of the TFT array layer 13, thereby effectively blocking the transverse light.

In a specific embodiment, optionally, a sectional shape of the groove 1310 on a first plane is trapezoidal or rectangular, and the first plane is perpendicular to the plane where the base substrate 11 is located and is perpendicular to an intersection line between the transition region 300 and the light-transmissive region 100. The sectional shape of the example groove 1310 in FIG. 8 is inverted trapezoidal, rectangular or positive trapezoidal, which is not limited herein.

In a specific embodiment, the sectional shape of the groove 1310 on the first plane may be set to include a bottom edge 1311, the bottom edge 1311 is an edge of the sectional shape close to the base substrate 11, and the length of the bottom edge 1311 is greater than or equal to 0.5 μm. At this time, the thickness of the first light-shielding segment 141 with which the groove 1310 is filled in a direction parallel to a plane of the base substrate 11, i.e., a transverse width, is greater than or equal to 0.5 μm, which ensures that the first light-shielding segment 141 sufficiently blocks the transverse light, and ensures the light-shielding effect.

In a specific embodiment, the sectional shape of the groove 1310 on the first plane may be set to include a bottom edge 1311 and two side edges 1312, and the first plane is perpendicular to the plane where the base substrate 11 is located and is perpendicular to an intersection line between the transition region 300 and the light-transmissive region 100. The bottom edge 1311 is an edge of the sectional shape close to the base substrate 11, and the two side edges 1312 are connected to the bottom edge 1311, respectively. An included angle α formed by an intersection of extension lines of the two side edges 1312 and facing towards the groove ranges from 40° to 80°. Alternatively, an included angle β formed by an intersection of an extension line of a side edge 1312 and an extension line of the bottom edge 1311 and facing towards the groove 1310 ranges from 110° to 120°.

In the preparation process of the groove 1310, the complete planarization layer 13 is formed firstly, and then a trenching process is performed on the planarization layer 13, where the trenching process generally adopts an etching process, and when the planarization layer 13 is etched, an inclination angle of the inner wall of the groove 1310 may be controlled. It should be understood that the inner wall of the groove 1310 needs to be attached to the first light-shielding segment 141, and meanwhile, the groove 1310 filled with the light-shielding material may encroach on an area of the light-transmissive region 100, so that in this specific embodiment, the included angle α is set to range from 40° to 80° or the included angle β is set to range from 110° to 120°, thereby controlling an inclination angle γ of the inner wall of the groove 1310 to range from 50° to 70°. Thus, it is ensured that the inner wall of the groove 1310 is smooth enough to be attached to the first light-shielding segment 141, and is steep enough to avoid excessively encroaching the area of the light-transmissive region 100.

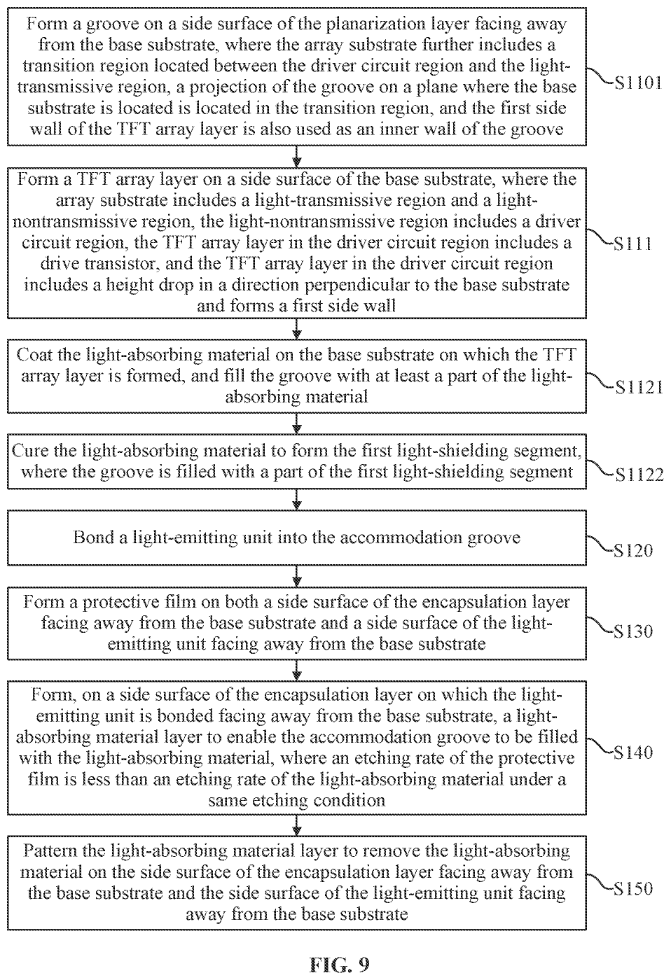

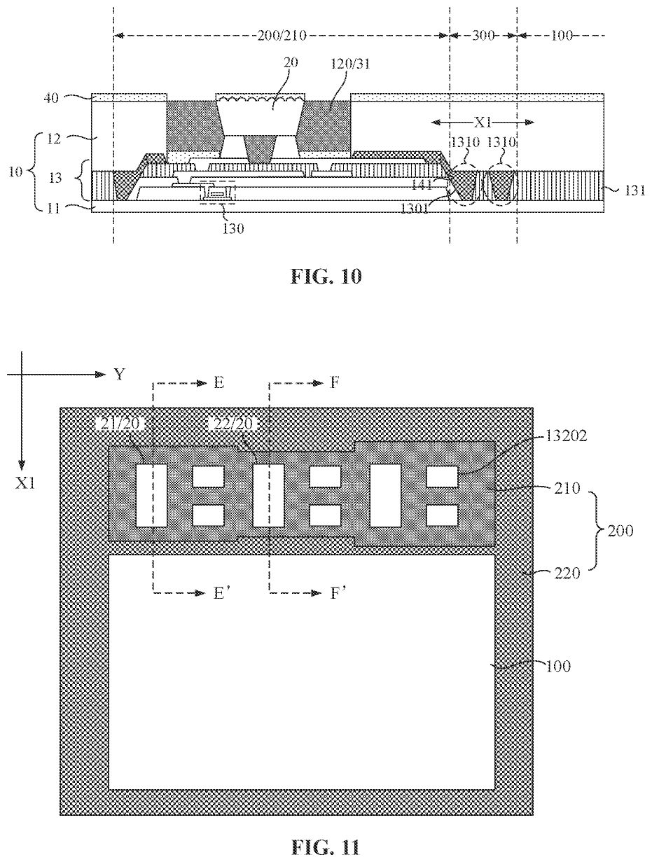

FIG. 10 is another sectional structural diagram of the display panel shown in FIG. 5 taken along direction AA′. Referring to FIGS. 5 and 10, in another embodiment, optionally, the planarization layer 131 is provided with multiple grooves 1310, projections of the grooves 1310 on the plane where the base substrate 11 is located extend along an intersection line between the transition region 300 and the light-transmissive region 100, the multiple grooves 1310 are sequentially arranged in parallel in a second direction X1, and the second direction X1 intersects an extension direction of the intersection line between the transition region 300 and the light-transmissive region 100.

In essence, in this embodiment, multiple grooves 1310 are disposed in the transition region 300. Exemplarily, the multiple grooves 1310 substantially extend in a row direction of the panel shown in FIG. 5 and are arranged in sequence in a column direction, that is, in the second direction X1. The multiple grooves 1310 may effectively block and accommodate the light-shielding material in the preparation of the light-shielding structure, particularly the first light-shielding segment 141, and prevent the light-shielding material from flowing into the light-transmissive region 100 to affect the transmittance of the light-transmissive region 100.

In addition, in other embodiments of the present disclosure, optionally, multiple separate groove structures may be disposed in the planarization layer, and projections of the multiple grooves on the plane where the base substrate is located are arranged in sequence along the intersection line between the transition region and the light-transmissive region. Here, the multiple separate grooves are also capable of accommodating a certain amount of the light-shielding material, so that the light-shielding material is prevented from flowing to the light-transmissive region, and meanwhile, the stress of the planarization layer can be released, and thus the warpage of the display panel is avoided.

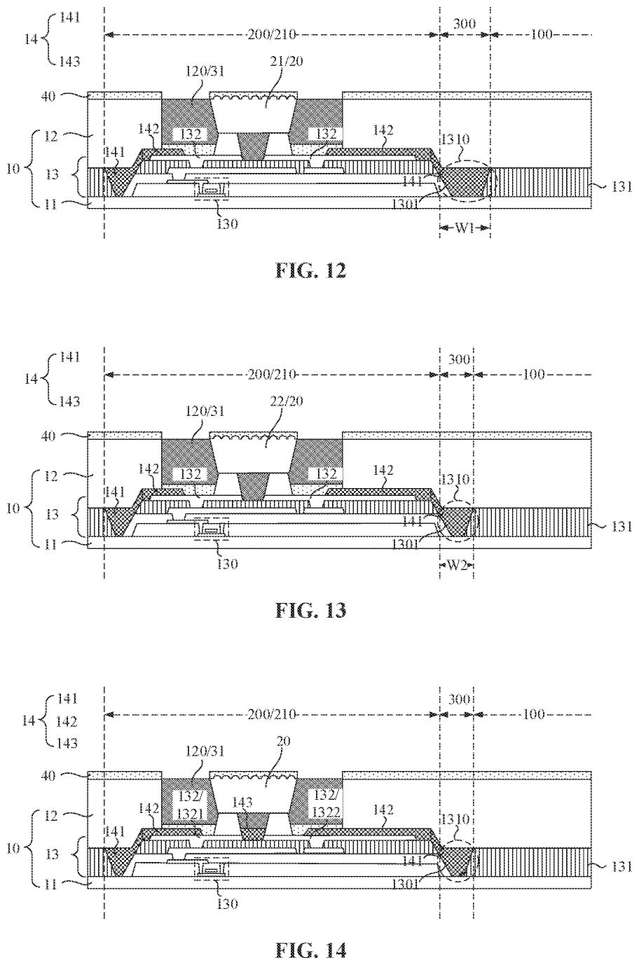

FIG. 11 is a top structural diagram of another display panel according to an embodiment of the present disclosure. FIGS. 12 and 13 are sectional structural diagrams of the display panel shown in FIG. 11 taken along directions EE′ and FF′, respectively. Referring to FIGS. 11 to 13, based on the above-described groove design on the planarization layer, optionally, light-emitting units 20 include a first color light-emitting unit 21 and a second color light-emitting unit 22, and a light-emitting brightness of the first color light-emitting unit 21 is greater than a light-emitting brightness of the second color light-emitting unit 22 under a same driving condition. The first color light-emitting unit 21 and the second color light-emitting unit 22 are sequentially arranged in the third direction Y. A length W1 of the groove 1310 adjacent to the first color light-emitting unit 21 is greater than a length W2 of the groove 1310 adjacent to the second color light-emitting unit 22 in the second direction X1, and the second direction X1 and the third direction Y intersect.

Here, the second direction X1 may be understood as the column direction, the third direction Y may be understood as the row direction, and the width of the groove 1310 in the second direction X1 is substantially a definition of the thickness of the first light-shielding segment 141 accommodated in the groove 1310 in the transverse direction. In this embodiment, the length W1 of the groove 1310 adjacent to the first color light-emitting unit 21 in the second direction X1 is set to be relatively larger, that is, the first light-shielding segment 141 adjacent to the first color light-emitting unit 21 is relatively wider in the transverse direction.

The light-emitting units in the embodiments of the present disclosure may be understood as LEDs, which are generally driven by the current, where the same driving condition means that the light-emitting units are driven to emit light by using the same drive current. The light-emitting units with different colors have different light-emitting efficiencies, and the light-emitting brightness of the light-emitting units under the same drive current is different. From this, it should be understood that, for the first color light-emitting unit 21 with higher light-emitting efficiency, its drive current is generally small, the corresponding drive transistor 130 is more sensitive to light influence; therefore, the groove 1310 partially accommodating the first light-shielding segment 141 is set to be relatively wider in the transverse direction in this embodiment, so that the thickness of a part of the first light-shielding segment 141 in the transverse direction may be increased, and the transverse light can be efficiently blocked, thereby preventing the drive transistor 130 from suffering the severe photoelectric characteristic changes due to light irradiation. Exemplarily, as shown in FIG. 11, the light-emitting units 20 may include light-emitting units with three colors of red, green, and blue, which are sequentially arranged in the row direction. According to the relationship of the light-emitting efficiency, i.e., G>R>B, correspondingly, the width of the groove adjacent to the light-emitting unit in the column direction may be set to be larger, whereby it is possible to obtain that the widths of the light-shielding structures 14 adjacent to the light-emitting units in the column direction are sequentially increased in order of blue, red, and green.

In addition to the design scheme of the above-described embodiments in which the first light-shielding segment is provided for the side wall of the TFT array layer, the present disclosure further provides another light-shielding structure. With continued reference to FIG. 8, optionally, the TFT array layer 13 includes a drive electrode 132, an end of the drive transistor 130 is coupled to the drive electrode 132, the drive electrode 132 is exposed to a side surface of the TFT array layer 13 facing away from the base substrate 11, a projection of the drive electrode 132 on the plane where the base substrate 11 is located at least partially overlaps with a projection of the accommodation groove 120 on the plane where the base substrate 11 is located, and the light-emitting unit 20 is electrically connected to the drive electrode 132. The light-shielding structure 14 further includes a second light-shielding segment 142, the second light-shielding segment 142 is located on a side of the TFT array layer 13 facing away from the base substrate 11, and a projection of the second light-shielding segment 142 on the plane where the base substrate is located at least partially overlaps with and at most partially overlaps with a projection of the drive electrode 132 on the plane where the base substrate is located.

Firstly, the drive transistor 130 is electrically connected to the light-emitting unit 20 through the drive electrode 132, and the drive transistor 130 may provide a drive signal for the light-emitting unit 20 through the drive electrode 132. Since the drive electrode 132 needs to be connected to the light-emitting unit 20, the drive electrode 132 needs to be exposed to a side surface of the TFT array layer 13 facing away from the base substrate 11, i.e., an upper surface of the TFT array layer 13. When the light-emitting unit 20 is bonded to the array substrate 10, the light-emitting unit 20 is in alignment bonding with the exposed drive electrode 132.

Since the drive electrode 132 is generally made of a metallic material such as silver or aluminum, the drive electrode 132 has a certain light reflecting capacity. However, the light reflection of the metal electrode may cause the display contrast to be poor for the display panel, and the display effect is affected. Based on this, in this embodiment, a second light-shielding segment 142 is further disposed in the light-shielding structure 14 and mainly used for covering the redundant drive electrode 132 so as to prevent the drive electrode 132 from reflecting the light emitted from the light-emitting unit 20 and the light incident from the outside. It should be understood that the second light-shielding segment 142 herein is substantially located on the upper surface of the TFT array layer 13 and covers a part of the drive electrode 132, while a part of the drive electrode 132 is also exposed for bonding the drive electrode 132 to the light-emitting unit 20.

With continued reference to FIG. 8, specifically, in order to ensure that at least a part of the drive electrode 132 is exposed from the light-shielding structure, optionally, the light-shielding structure 14 includes an electrode opening 140, and a projection of the electrode opening 140 on the plane where the base substrate 11 is located at least partially overlaps with the projection of the drive electrode 132 on the plane where the base substrate 11 is located.

Based on the light-shielding structure described above, in a specific embodiment, optionally, a distance D1 between an edge of the electrode opening 140 facing away from the light-emitting unit 20 and the light-emitting unit 20 is less than or equal to 7 μm. In this case, a certain gap exists between the edge of the electrode opening 140 and the light-emitting unit 20, so that a certain amount of redundancy may be provided for the alignment bonding of the light-emitting unit 20, thereby preventing the light-emitting unit 20 from being effectively bonded to the drive electrode 132 due to the alignment error, and preventing the light-emitting unit 20 from being poorly connected.

In a specific embodiment, optionally, a distance D2 between the edge of the accommodation groove 120 and the light-emitting unit 20 is less than or equal to 10 μm. At this time, a gap also exists between the inner wall of the accommodation groove 120 and the light-emitting unit 20, and when the light-emitting unit 20 is aligned to the accommodation groove 120, a certain redundancy may also exist, which can prevent the light-emitting unit 20 from being unable to be disposed in the accommodation groove 120 due to the alignment error, and prevent the bonding from being unable to be achieved. Further, since the accommodation groove 120 is filled with the light-absorbing material 31, the distance D2 between the edge of the accommodation groove 120 and the light-emitting unit 20 may be set to be greater than the distance D1 between the edge of the electrode opening 140 facing away from the light-emitting unit 20 and the light-emitting unit 20. In this case, the light-absorbing material with which the accommodation groove 120 is filled overlaps with the light-shielding structure 14 in projection.

Since the surface of the TFT array layer 13 outside the region covered by the light-emitting unit may be shielded from light by using the light-absorbing material and the light-shielding structure 14, whereby an internal structure of the TFT array layer 13 is not disturbed by the external light, and meanwhile, the display contrast is not affected by the reflected light.

FIG. 14 is another sectional structural diagram of the display panel shown in FIG. 5 taken along direction AA′. Referring to FIG. 14, in another embodiment, optionally, the light-shielding structure 14 further includes a third light-shielding segment 143, the drive electrode 132 includes a first electrode 1321 and a second electrode 1322, and a projection of a gap between the first electrode 1321 and the second electrode 1322 on the plane where the base substrate 11 is located is located in a projection of the third light-shielding segment 143 on the plane where the base substrate 11 is located.

The first electrode 1321 and the second electrode 1322 may be understood as a cathode and an anode, and in this embodiment, two electrode openings in the light-shielding structure 14 are provided for exposing at least a part of the structures of the first electrode 1321 and the second electrode 1322, respectively. A region between two electrodes is still shielded from light by the light-shielding structure, i.e. the third light-shielding segment 143. It should be understood by those skilled in the art that the arrangement of the third light-shielding segment 143 here depends not only on the design of the scheme but also on the preparation process. When the size of the light-emitting unit 20 is relatively small and the spacing between the two electrodes is small, the preparation of the third light-shielding segment 143 is limited to the resolution of exposure.

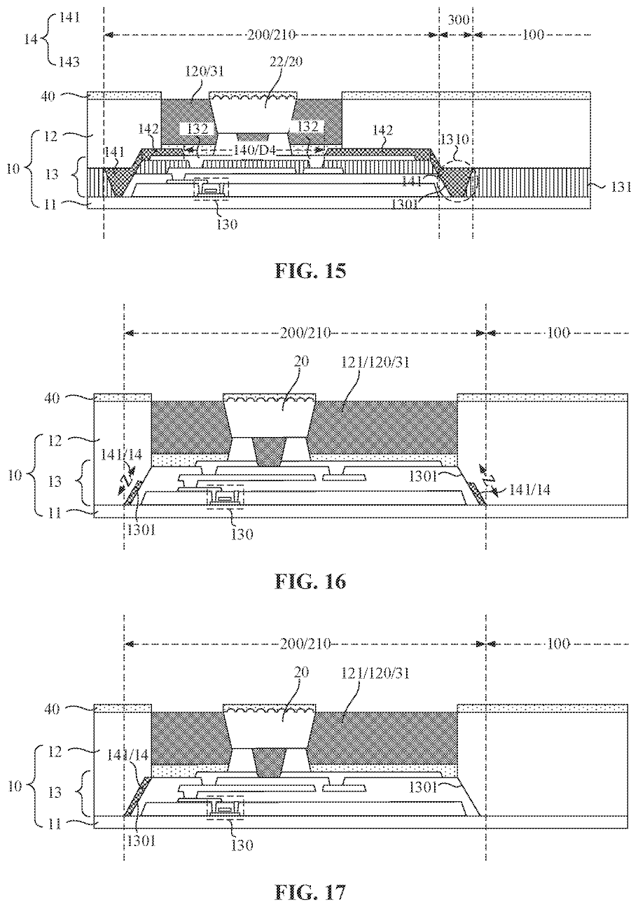

FIG. 15 is a sectional structural diagram of the display panel shown in FIG. 5 taken along direction BB′. Referring to FIGS. 5, 8, and 15, optionally, light-emitting units 20 include a first color light-emitting unit 21 and a second color light-emitting unit 22, and a light-emitting brightness of the first color light-emitting unit 21 is greater than a light-emitting brightness of the second color light-emitting unit 22 under a same driving condition. An electrode opening 140 in a light-shielding structure 14 at a position where the first color light-emitting unit 21 is located is less than an electrode opening 140 in a light-shielding structure 14 at a position where the second color light-emitting unit 22 is located. The width of the electrode opening 140 in a direction parallel to the base substrate 11 shown in FIG. 8 is D3, the width of the electrode opening 140 in the direction parallel to the base substrate 11 shown in FIG. 15 is D4, and D3<D4.

As described above, the light-emitting units with different colors have different light-emitting efficiencies, and the light-emitting brightness of the light-emitting units under the same drive current is different. From this, it should be understood that, for the light-emitting unit 21 with larger light-emitting brightness, the light reflected by the drive electrode 132 of the light-emitting unit 21 is stronger, and the influence on the display contrast is larger. In view of this, in this embodiment, for the first color light-emitting unit 21 with larger light-emitting brightness, the electrode opening 140 corresponding to the first color light-emitting unit 21 is set to be relatively smaller, so that the light reflection of light-emitting units with different colors on the drive electrode 132 may be balanced, different regions of the display panel are prevented from having different light reflection effects, the electrode openings are arranged in a differentiation manner on the basis that the light-shielding structure shields the drive electrode, thereby facilitating the display uniformity of the display panel to a certain extent. Exemplarily, the light-emitting units 20 may include light-emitting units with three colors of red, green, and blue. According to the relationship of the light-emitting brightness, i.e., G>R>B, correspondingly, an electrode opening of a green light-emitting unit may be set to be minimum, an electrode opening of a red light-emitting unit may be set to be medium, and an electrode opening of a blue light-emitting unit may be set to be maximum.

It is also to be supplemented that the first light-shielding segment in the light-shielding structure is not limited to the case shown in the above-described embodiments, and those skilled in the art may also design the first light-shielding segment according to actual requirements.

FIGS. 16 and 17 are two other sectional structural diagrams of the display panel shown in FIG. taken along direction AA′. In other embodiments of the present disclosure, exemplarily, referring to FIG. 16, optionally, the first light-shielding segment 141 covers a part of the first side wall 1301 of the TFT array layer 13 in the first direction Z. Referring to FIG. 17, optionally, the first light-shielding segment 141 covers at least a region of the first side wall 1301 of the TFT array layer 13 close to the drive transistor 130. Those skilled in the art may reasonably modify the first light-shielding segment in the light-shielding structure according to actual requirements, and various reasonable modifications based on the embodiments of the present disclosure shall fall into the scope of protection of the present disclosure.

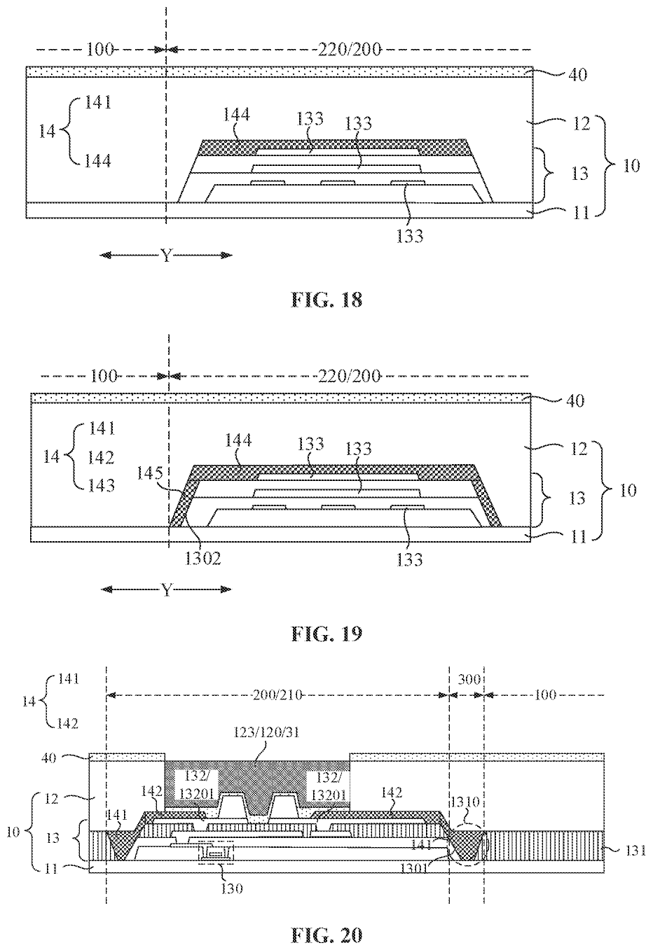

FIGS. 18 and 19 are two other sectional structural diagrams of the display panel shown in FIG. 5 taken along direction CC′. Referring to FIGS. 5 and 18, the light-nontransmissive region 200 further includes a wire region 220, and the TFT array layer 13 in the wire region 220 includes at least one wire 133. The light-shielding structure 14 may further include a fourth light-shielding segment 144, the fourth light-shielding segment 144 is located on a side surface of the TFT array layer 13 in the wire region 220 facing away from the base substrate 11, and a projection of the at least one wire 133 on the plane where the base substrate 11 is located is located in a projection of the fourth light-shielding segment 144 on the plane where the base substrate 11 is located.

Further, referring to FIG. 19, the TFT array layer 13 in the wire region includes a height drop in a direction perpendicular to the base substrate 11 and forms a second side wall 1302. Based on this, optionally, the light-shielding structure 14 further includes a fifth light-shielding segment 145, and the fifth light-shielding segment covers at least a part of the second side wall 1302 of the TFT array layer 13 in the wire region.

Similarly, the driver circuit in the TFT array layer 13 may be provided with a wire in addition to the drive transistor. Specifically, the wires 133 of the TFT array layer 13 in the wire region 220 may include a power supply signal line and a data signal line, thereby forming a light-nontransmissive wire region 220. The wire 133 in the wire region 220 is also generally made of metal, that is, also has a light-reflecting characteristic, and easily causes the deterioration of display contrast. In view of this, in the embodiments of the present disclosure, the fourth light-shielding segment 144 and the fifth light-shielding segment 145 are disposed in the light-shielding structure 14, and the fourth light-shielding segment 144 and the fifth light-shielding segment 145 are disposed on the side surface (i.e., the upper surface) of the TFT array layer 13 away from the base substrate 11 and on the second side wall 1302, so that the wire 133 in the wire region 220 may be covered, so that the wire 133 of TFT array layer 13 in the wire region 220 is prevented from reflecting the external incident light, and thus the display effect is improved.

With continued reference to FIG. 5, it is also to be supplemented that the wire region 220 is located on at least one side of the light-transmissive region 100 in the third direction Y, and the driver circuit region 210 is located on at least one side of the light-transmissive region 100 in the fourth direction X2. The third direction Y and the fourth direction X2 intersect and are both parallel to the plane where the base substrate 11 is located.

Further, optionally, the light-emitting unit 20 is located in the driver circuit region 210, multiple light-emitting units 20 are provided and sequentially arranged in the third direction Y and constitute a group of light-emitting units 20, and the driver circuit region 210 includes at least one group of light-emitting units 20 in the fourth direction X2.

Exemplarily, the third direction Y may be understood as the row direction, the fourth direction X2 may be understood as the column direction, the light-transmissive region 100 and the driver circuit region 210 adjacent to the light-transmissive region 100 in the display panel constitute one pixel unit region (not shown in the drawings) of the display panel, and the display panel essentially consists of multiple pixel unit regions arranged in an array. A group of light-emitting units 20 in each pixel unit region may include three light-emitting units of red, green, and blue arranged in sequence in the row direction. Moreover, in order to ensure the light-emitting brightness of each pixel unit, one or more groups of light-emitting units may be disposed in the column direction, which is not limited herein.

FIG. 20 is a sectional structural diagram of the display panel shown in FIG. 5 taken along direction DD′. Referring to FIGS. 5 and 20, in a practical application, the drive electrode 132 in the driver circuit region 210 of the display panel generally includes a main drive electrode 13201 and a backup drive electrode 13202, and the backup drive electrode 13202 is activated when the light-emitting unit 20 and the main drive electrode 13201 are in poor electrical connection. Specifically, for the same light-emitting unit 20, a group of main drive electrodes 13201 and a group of backup drive electrodes 13202 exist, and the light-emitting unit is pre-bonded to the main drive electrodes 13201, and then a lighting test is performed to detect whether the light-emitting unit 20 is poorly connected. When the connection failure exists, one light-emitting unit 20 is bonded to the corresponding backup drive electrode 13202 as a replacement. Considering that the backup drive electrode 13202 has the light reflecting property, while the encapsulation layer 12 is formed and the accommodation groove 120 is formed by trenching, the third accommodation groove 123 as shown in the drawings may be formed by trenching a region corresponding to the backup drive electrode 13202 of the encapsulation layer 12 which is not bonded with the light-emitting unit 20, and the third accommodation groove 123 is filled with the light-absorbing material 31. A projection of the light-absorbing material 31 in the third accommodation groove 123 on the plane where the base substrate 11 is located covers a projection of the backup drive electrode 13202 on the plane where the base substrate 11 is located, so that the backup drive electrode 13202 may be shielded from light, thereby avoiding the reflection of the external incident light by the backup drive electrode 13202, and improving the display effect.

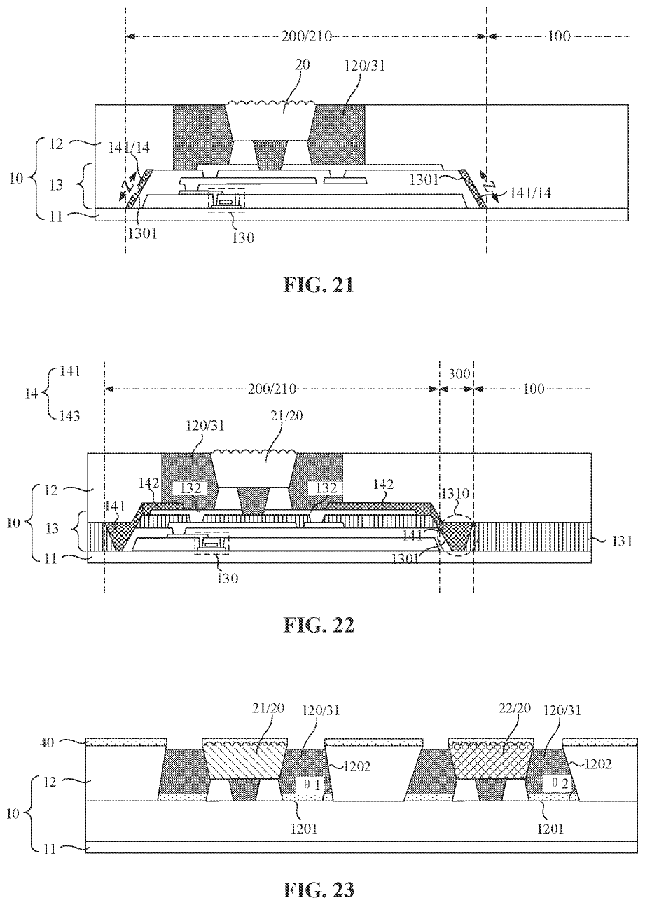

Based on the various embodiments in which the light-shielding structure is disposed in the display panel, the present disclosure further provides another type of display panel. FIGS. 21 and 22 are partial sectional structural diagrams of two other display panels according to an embodiment of the present disclosure. With reference to FIGS. 21 and 22, the display panels correspond to the display panels shown in FIG. 6 and FIG. 15, respectively. According to comparison, it can be seen that the differences are as follows: the protective layer 40 is not disposed in the display panel of this embodiment. It needs to be supplemented that the array substrate 10 of the display panel shown in FIG. 21 is provided with the light-shielding structure 14, the light-shielding structure 14 includes the first light-shielding segment 141, and the first light-shielding segment 141 covers at least a part of the first side wall 1301 of the TFT array layer 13. On the basis of the structure of the display panel shown in FIG. 21, in the array substrate 10 of the display panel shown in FIG. 22, a side surface of the planarization layer 131 facing away from the base substrate 11 is provided with the groove 1310, the first side wall 1301 of the TFT array layer 13 is also used as the inner wall of the groove 1310, and the groove 1310 is filled with a part of the first light-shielding segment 141. Moreover, the light-shielding structure 14 further includes the second light-shielding segment 142, the second light-shielding segment 142 is located on the side of the TFT array layer 13 facing away from the base substrate 11, and the projection of the second light-shielding segment 142 on the plane where the base substrate is located at least partially overlaps with and at most partially overlaps with the projection of the drive electrode 132 on the plane where the base substrate is located.

Of course, the display panels shown in FIGS. 21 and 22 are only two examples. Based on the design of the light-shielding structure in the foregoing embodiments of the present disclosure, those skilled in the art may also obtain, under the design concept of removing the protective film 40, the display panel in which the light-shielding structure is included but the protective film is not included, and the light-shielding structure includes any one of the first light-shielding segment, the second light-shielding segment, the third light-shielding segment, the fourth light-shielding segment, and the fifth light-shielding segment, and reasonable variations obtained on this basis fall within the scope of protection of the present application.

In addition to the design scheme of the light-shielding structure in the above embodiment, the present disclosure further provides a research for the accommodation groove. With continued reference to FIG. 2, in the display panel, the sectional shape of the accommodation groove 120 in the second plane is rectangular or trapezoidal, and the second plane is perpendicular to the plane where the base substrate 11 is located. Specifically, the sectional shape of the accommodation groove 120 on the second plane includes a bottom edge 1201 and two side edges 1202. The bottom edge 1201 is an edge of the sectional shape close to the base substrate 11, and the two side edges 1202 are connected to the bottom edge 1201, respectively. An included angle θ formed by an intersection of an extension line of a side edge of the side edge 1202 and an extension line of the bottom edge 1201 and facing towards the accommodation groove 120 ranges from 80° to 110°.

The included angle θ formed by the intersection of the extension line of the side edge 1202 and the extension line of the bottom edge 1201 and facing towards the accommodation groove 120 is essentially an inclination angle of the inner wall of the accommodation groove 120. The inclination angle of the inner wall of the accommodation groove 120 being set to range from 80° to 110° is essentially to define the sectional shape of the accommodation groove 120 to be positive trapezoidal, rectangular, or inverted trapezoidal. It should be understood that when the inclination angle θ is less than 90°, the sectional shape of the accommodation groove 120 is positive trapezoidal; when the inclination angle θ is equal to 90°, the sectional shape of the accommodation groove 120 is rectangular; and when the inclination angle θ is greater than 90°, the sectional shape of the accommodation groove 120 is inverted trapezoidal. The drawings show only by example that the sectional shape of the accommodation groove is rectangular, i.e., θ=90°, and in other embodiments, alternatively, the sectional shape may be a positive trapezoid or an inverted trapezoid, etc., which is not limited herein.

With continued reference to FIG. 2, the light-emitting unit 20 includes a first surface 201 and a second surface 202 away from each other, the first surface 201 is a side surface of the light-emitting unit close to the base substrate 11, the second surface 202 is a side surface of the light-emitting unit facing away from the base substrate 11, and the first surface 201 is provided with an electrode. In a direction perpendicular to the base substrate 11, a height H0 of a side surface of the light-absorbing material 31 facing away from the base substrate 11 is greater than a height H1 of the first surface 201 and is less than a height H2 of the second surface 202.

As shown in FIG. 2, the first surface 201 of the light-emitting unit 20 is substantially the lower surface thereof, and the second surface 202 of the light-emitting unit 20 is substantially the upper surface thereof. The height of the light-absorbing material 31 is defined to be between the upper surface and the lower surface of the light-emitting unit 20, which is substantially to define that the light-absorbing material layer is suitably over-etched during the preparation process, and the redundant light-absorbing material on the upper surface of the light-emitting unit 20 may be completely removed during the over-etching process.

With continued reference to FIG. 2, optionally, the height H0 of the side surface of the light-absorbing material 31 facing away from the base substrate 11 is less than a height H3 of a side surface of the protective film 40 facing away from the base substrate 11.

As can be seen from the above, the structure essentially defines that the light-absorbing material layer 30 is suitably over-etched during preparation. It should be understood that after the light-absorbing material on the surface of the protective film 40 is etched away, and when the etching is continued, that is, the over-etching is performed, the height of the surface of the light-absorbing material 31 in the accommodation groove 120 is further reduced, so that the upper surface of the protective film 40 may be higher than the height of the upper surface of the light-absorbing material 31. Under the over-etching condition, the redundant light-absorbing material on the upper surface of the light-emitting unit 20 may be completely removed.

FIGS. 23, 24 and 25 are partial sectional structural diagrams of three other display panels according to an embodiment of the present disclosure. Referring to FIGS. 23, 24 and 25, optionally, light-emitting units 20 include a first color light-emitting unit 21 and a second color light-emitting unit 22, and a light-emitting brightness of the first color light-emitting unit 21 is greater than a light-emitting brightness of the second color light-emitting unit 22 under a same driving condition. An included angle, which is formed by an intersection of an extension line of a side edge 1202 and an extension line of a bottom edge 1201 in an accommodation groove 120 where the first color light-emitting unit 21 is located and faces towards the accommodation groove 120 where the first color light-emitting unit 21 is located, is a first included angle θ1, and an included angle, which is formed by an intersection of an extension line of a side edge of the side edges 1202 and an extension line of a bottom edge 1201 in an accommodation groove 120 where the second color light-emitting unit 22 is located and faces towards the accommodation groove 120 where the second color light-emitting unit 22 is located, is a second included angle θ2.

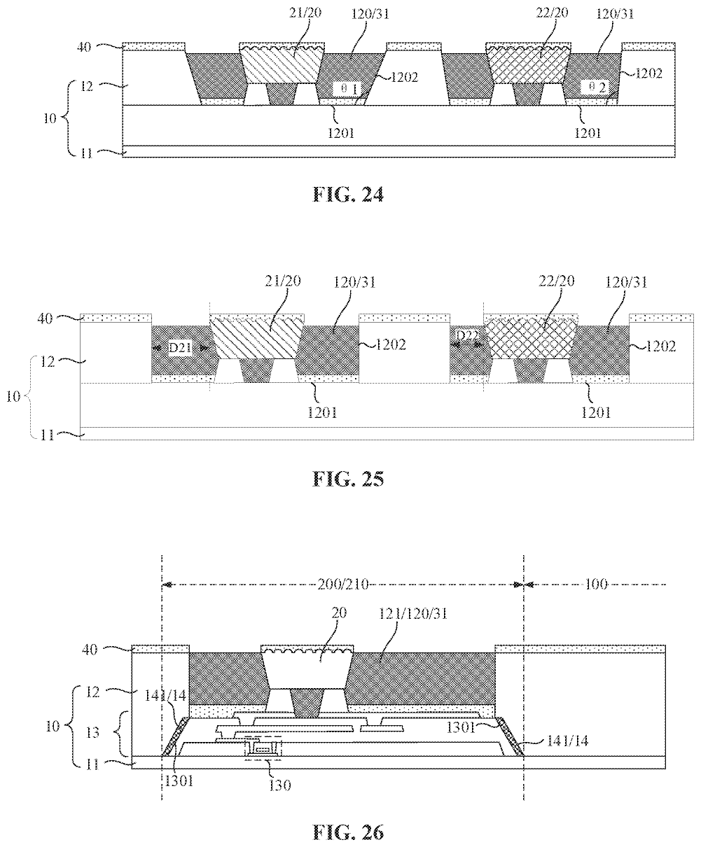

Referring to FIG. 23, when the included angle formed by the intersection of the extension line of the side edge 1202 and the extension line of the bottom edge 1201 and facing towards the accommodation groove 120 is less than 90°, the first included angle θ1 may be set to be greater than the second included angle θ2. Referring to FIG. 24, when the included angle formed by the intersection of the extension line of the side edge 1202 and the extension line of the bottom edge 1201 and facing towards the accommodation groove 120 is greater than 90°, the first included angle θ1 may be set to be greater than the second included angle θ2. Referring to FIG. 25, when the included angle formed by the intersection of the extension line of the side edges 1202 and the extension line of the bottom edge 1201 and facing towards the accommodation groove 120 is equal to 90°, a distance D21 between the side edge 1202 in the accommodation groove 120 where the first color light-emitting unit 21 is located and the first color light-emitting unit 21 is greater than a distance D22 between the side edge 1202 in the accommodation groove 120 where the second color light-emitting unit 22 is located and the second color light-emitting unit 22.

As described above, the light-emitting units with different colors have different light-emitting efficiencies, and the light-emitting brightness of the light-emitting units under the same drive current is different. Considering that one of the functions of the accommodation groove 120 is to block the light emitted from the light-emitting unit 20 in the transverse direction by using the light-absorbing material 31 with which the accommodation groove 120 is filled, in order to balance the light shielding effect in the transverse direction for the light-emitting units 20 with different colors, optionally, an upper opening diameter of the accommodation groove 120 in which the light-emitting unit 20 having a higher light-emitting brightness is located may be set to be wider, that is, the upper half portion of the light-absorbing material in the accommodation groove 20 has a thicker thickness in the transverse direction, thereby better absorbing the light emitted from the light-emitting unit 20 in the transverse direction. Specifically, in FIGS. 23, 24 and 25, the sectional shapes of the accommodation grooves 120 are configured to be positive trapezoidal, inverted trapezoidal and rectangular, respectively. In order to ensure that the accommodation groove has the above-described differential design of the upper opening diameter, when the inclination angle θ of the inner wall of the accommodation groove 120 is less than 90°, that is, the sectional shape of the accommodation groove 120 is positive trapezoidal, the inner wall of the accommodation groove 120 corresponding to the first color light-emitting unit 21 having a high light-emitting brightness may be set to be relatively steeper, that is, θ1>θ2. Similarly, when the inclination angle θ of the inner wall of the accommodation groove 120 is greater than 90°, that is, when the sectional shape of the accommodation groove 120 is inverted trapezoidal, the inclination angle of the inner wall of the accommodation groove 120 corresponding to the first color light-emitting unit 21 having a high light-emitting brightness may be set to be relatively larger, that is, θ1>θ2. Similarly, when the inclination angle θ of the inner wall of the accommodation groove 120 is equal to 90°, the sectional shape of the accommodation groove 120 is rectangular, and the inclination angles of the side walls are both 90°, and the distance between the first color light-emitting unit 21 having a high light-emitting brightness and the inner wall of the accommodation groove 120 may be set to be larger, that is, D21>D22. In a practical application, the accommodation grooves of the red light-emitting unit, the green light-emitting unit, and the blue light-emitting unit in which the light-emitting brightness satisfies the relationship of G>R>B may be differentiated according to the above-described principle, which will not be exemplified here.

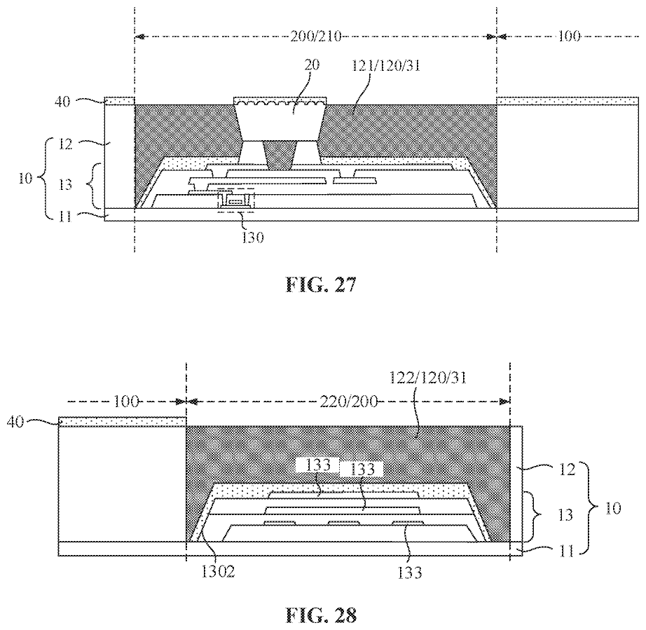

FIGS. 26 and 27 are partial sectional structural diagrams of two other display panels according to an embodiment of the present disclosure. Referring to FIGS. 26 and 27, an array substrate 10 includes a light-transmissive region 100 and a light-nontransmissive region 200, and the light-nontransmissive region 200 includes a driver circuit region 210. The array substrate 10 further includes a TFT array layer 13, the TFT array layer 13 is disposed between a base substrate 11 and an encapsulation layer 12, and the TFT array layer 13 in the driver circuit region 210 includes a drive transistor 130 and a drive electrode 132, an end of the drive transistor 130 is coupled to the drive electrode 132, and the drive electrode 132 is exposed to a side surface of the TFT array layer 13 facing away from the base substrate 11.

Optionally, accommodation grooves 120 include a first accommodation groove 121, a light-emitting unit 20 is located in the first accommodation groove 121, the first accommodation groove 121 is filled with a light-absorbing material 31, the light-emitting unit 20 is electrically connected to the drive electrode 132, and a projection of the drive electrode 132 on a plane where the base substrate 11 is located is located in a projection of the first accommodation groove 121 on the plane where the base substrate 11 is located.

Since the first accommodation groove 121 is filled with the light-absorbing material 31, the light-absorbing material 31 may be used for shielding the drive electrode 132 on the array substrate 10 in the lower layer from light while wrapping the light-emitting unit 20, so that the drive electrode 132 is prevented from reflecting the light emitted from the light-emitting unit and light incident from the outside, thereby improving the contrast of the display panel.

Referring to FIG. 27, in this embodiment, the TFT array layer 13 in the driver circuit region includes a height drop in a direction perpendicular to the base substrate 11 and forms a first side wall 1301. Based on this, at least a part of a projection of the first side wall 1301 on the plane where the base substrate 11 is located may be located in the projection of the first accommodation groove 121 on the plane where the base substrate 11 is located.

In this case, the light-absorbing material 31 in the first accommodation groove 121 not only wraps the light-emitting unit 20, covers the drive electrode 132 on the TFT array layer 13, but also covers the first side wall 1301 of the TFT array layer 13. Therefore, the light-absorbing material 31 in the first accommodation groove 121 may be used for shielding the light-emitting unit 20, the drive electrode 132 and the inside of the TFT array layer 13 from light at the same time, thereby reducing the transverse cross-talk of the light-emitting unit and the light reflection of the drive electrode, avoiding the interference of the drive transistor by external light, and ensuring the stability of the electrical properties of the driver circuit.

It should be noted that, exemplarily, the upper surface and the side wall of the TFT array layer 13 in FIGS. 26 and 27 are provided with no or only a partial light-shielding structure, and in a practical application, optionally, the first light-shielding segment, the second light-shielding segment, and the third light-shielding segment in the foregoing embodiments may be disposed in the TFT array layer in the driver circuit region 210, so that the double light-shielding on the internal structure of the TFT array layer and the drive electrode of the surface thereof is achieved through the light-absorbing material 31 in the first accommodation groove 121, the first light-shielding segment, the second light-shielding segment and the third light-shielding segment, thereby optimizing the light-shielding effect.

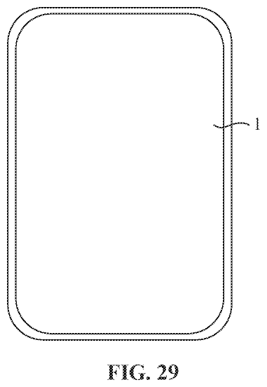

FIG. 28 is a partial sectional structural diagram of another display panel according to an embodiment of the present disclosure. Referring to FIG. 28, the accommodation grooves 120 further include a second accommodation groove 122, and the second accommodation groove 122 is filled with the light-absorbing material 31. The light-nontransmissive region 200 further includes a wire region 220, the TFT array layer 13 in the wire region 220 includes at least one wire 133, and a projection of the at least one wire 133 on the plane where the base substrate 11 is located is located in a projection of the second accommodation groove 122 on the plane where the base substrate 11 is located.

Here, the light-absorbing material 31 with which the second accommodation groove 122 is filled with may cover the wires 133 in the wire region 220, so that the light reflection of the wires 133 to the light incident from the outside can be avoided, and the contrast of the display panel may be improved. Similarly, in FIG. 28, for example, no light-shielding structure is disposed on the upper surface (i.e., the side wall) of the TFT array layer 13. In a practical application, optionally, the fourth light-shielding segment and the fifth light-shielding section in the foregoing embodiments may be disposed on the TFT array layer 13 in the wire region 220, so that the double light-shielding on the wires inside the TFT array layer is achieved through the light-absorbing material 31 in the second accommodation groove 122, the fourth light-shielding segment and the fifth light-shielding segment, thereby optimizing the light-shielding effect.

Based on the same inventive concept, an embodiment of the present disclosure further provides a display device. FIG. 29 is a structural diagram of a display device according to an embodiment of the present disclosure. Referring to FIG. 29, the display device may include any one of the display panels 1 provided in the above-described embodiment. Moreover, since the display device is prepared through the display panel described above, the display device has the same or corresponding technical effect as the display panel. It should be noted that the display device further includes other devices for supporting the normal operation of the display device. Specifically, the display device may be a mobile phone, a tablet, a computer, a television, a wearable intelligent device, and the like, which are limited in the embodiments of the present disclosure.

It should be noted that the above are merely preferred embodiments of the present disclosure and the technical principles applied herein. It should be understood by those skilled in the art that the present disclosure is not limited to the particular embodiments described herein. For those skilled in the art, various apparent modifications, adaptations, combinations and substitutions may be made without departing from the scope of the present disclosure. Therefore, although the present disclosure has been described in detail through the above embodiments, the present disclosure is not limited to the above embodiments and may include more other equivalent embodiments without departing from the concept of the present disclosure. The scope of the present disclosure is determined by the scope of the appended claims.

What is claimed is:

1. A display panel, comprising:
an array substrate comprising a base substrate and an encapsulation layer located on a side of the base substrate, wherein a side surface of the encapsulation layer facing away from the base substrate is provided with an accommodation groove; and
a light-emitting unit located in the accommodation groove, wherein the accommodation groove is filled with a light-absorbing material, a protective film is formed on both a side surface of the encapsulation layer facing away from the base substrate and a side surface of the light-emitting unit facing away from the base substrate, and an etching rate of the protective film is less than an etching rate of the light-absorbing material under a same etching condition.

2. The display panel of claim 1, wherein
the array substrate comprises a light-transmissive region and a light-nontransmissive region, and the light-nontransmissive region comprises a driver circuit region;
the array substrate further comprises a thin film transistor (TFT) array layer located between the base substrate and the encapsulation layer, the TFT array layer in the driver circuit region comprises a drive transistor, and the TFT array layer in the driver circuit region comprises a height drop in a direction perpendicular to the base substrate and forms a first side wall; and
a light-shielding structure is disposed in the array substrate, the light-shielding structure comprises a first light-shielding segment, and the first light-shielding segment covers at least a part of the first side wall of the TFT array layer.

3. The display panel of claim 2, wherein the first light-shielding segment comprises a first side edge and a second side edge away from each other in a first direction, wherein
the first direction is perpendicular to an edge line of a side of the driver circuit region facing towards the light-transmissive region and is parallel to a plane where the first side wall of the TFT array layer is located; and
the first side edge extends to a side surface of the TFT array layer facing away from the base substrate, and the second side edge extends to the base substrate.

4. The display panel of claim 2, wherein
the TFT array layer comprises a planarization layer, and a side surface of the planarization layer facing away from the base substrate is provided with a groove;
the array substrate further comprises a transition region located between the driver circuit region and the light-transmissive region, and a projection of the groove on a plane where the base substrate is located is located in the transition region; and
the first side wall of the TFT array layer is also used as an inner wall of the groove, and the groove is filled with a part of the first light-shielding segment.

5. The display panel of claim 4, wherein
the groove penetrates through the planarization layer, and a surface of the base substrate is used as a bottom of the groove; and the groove is filled with a part of the first light-shielding segment, and the part of the first light-shielding segment is in contact with the surface of the base substrate; and
a sectional shape of the groove on a first plane comprises a bottom edge and two side edges, and the first plane is perpendicular to the plane where the base substrate is located and is perpendicular to an intersection line between the transition region and the light-transmissive region, wherein
the bottom edge is an edge of the sectional shape close to the base substrate, and the two side edges are connected to the bottom edge, respectively; and
an included angle formed by an intersection of extension lines of the two side edges and facing towards the groove ranges from 40° to 80°.

6. The display panel of claim 4, wherein the planarization layer is provided with a plurality of grooves, projections of the plurality of grooves on the plane where the base substrate is located extend along an intersection line between the transition region and the light-transmissive region, the plurality of grooves are sequentially arranged in parallel in a second direction, and the second direction intersects an extension direction of the intersection line between the transition region and the light-transmissive region.

7. The display panel of claim 2, wherein
the TFT array layer further comprises a drive electrode, an end of the drive transistor is coupled to the drive electrode, the drive electrode is exposed to a side surface of the TFT array layer facing away from the base substrate, a projection of the drive electrode on a plane where the base substrate is located at least partially overlaps with a projection of the accommodation groove on the plane where the base substrate is located, and the light-emitting unit is electrically connected to the drive electrode;
the light-shielding structure further comprises a second light-shielding segment, the second light-shielding segment is located on a side of the TFT array layer facing away from the base substrate, and a projection of the second light-shielding segment on the plane where the base substrate is located at least partially overlaps with and at most partially overlaps with a projection of the drive electrode on the plane where the base substrate is located; and
the light-shielding structure comprises an electrode opening, and a projection of the electrode opening on the plane where the base substrate is located at least partially overlaps with the projection of the drive electrode on the plane where the base substrate is located.

8. The display panel of claim 7, wherein
a plurality of light-emitting units are provided, the plurality of light-emitting units comprise a first color light-emitting unit and a second color light-emitting unit, and a light-emitting brightness of the first color light-emitting unit is greater than a light-emitting brightness of the second color light-emitting unit under a same driving condition; and
an electrode opening in a light-shielding structure at a position where the first color light-emitting unit is located is less than an electrode opening in a light-shielding structure at a position where the second color light-emitting unit is located.

9. The display panel of claim 7, wherein
the light-nontransmissive region further comprises a wire region, and the TFT array layer in the wire region comprises at least one wire; and
the light-shielding structure further comprises a fourth light-shielding segment, the fourth light-shielding segment is located on a side surface of the TFT array layer in the wire region facing away from the base substrate, and a projection of the at least one wire on the plane where the base substrate is located is located in a projection of the fourth light-shielding segment on the plane where the base substrate is located.

10. The display panel of claim 9, wherein
the TFT array layer in the wire region comprises a height drop in the direction perpendicular to the base substrate and forms a second side wall; and
the light-shielding structure further comprises a fifth light-shielding segment, and the fifth light-shielding segment covers at least a part of the second side wall of the TFT array layer in the wire region.

11. The display panel of claim 9, wherein
the wire region is located on at least one side of the light-transmissive region in a third direction, and the driver circuit region is located on at least one side of the light-transmissive region in a fourth direction, wherein the third direction and the fourth direction intersect and are both parallel to the plane where the base substrate is located; and
the light-emitting unit is located in the driver circuit region, a plurality of light-emitting units are provided and sequentially arranged in the third direction and constitute a group of light-emitting units, and the driver circuit region comprises at least one group of light-emitting units in the fourth direction.

12. The display panel of claim 1, wherein a sectional shape of the accommodation groove on a second plane comprises a bottom edge and two side edges, wherein
the bottom edge is an edge of the sectional shape close to the base substrate, and the two side edges are connected to the bottom edge, respectively; and
an included angle formed by an intersection of an extension line of a side edge of the side edges and an extension line of the bottom edge and facing towards the accommodation groove ranges from 80° to 110°.

13. The display panel of claim 12, wherein
a plurality of light-emitting units are provided, the plurality of light-emitting units comprise a first color light-emitting unit and a second color light-emitting unit, and a light-emitting brightness of the first color light-emitting unit is greater than a light-emitting brightness of the second color light-emitting unit under a same driving condition;
an included angle, which is formed by an intersection of an extension line of a side edge and an extension line of a bottom edge in an accommodation groove where the first color light-emitting unit is located and faces towards the accommodation groove where the first color light-emitting unit is located, is a first included angle, and an included angle, which is formed by an intersection of an extension line of a side edge and an extension line of a bottom edge in an accommodation groove where the second color light-emitting unit is located and faces towards the accommodation groove where the second color light-emitting unit is located, is a second included angle;
in a case where the included angle formed by the intersection of the extension line of the side edge and the extension line of the bottom edge and facing towards the accommodation groove is less than or greater than 90°, the first included angle is greater than the second included angle;
and in a case where the included angle formed by the intersection of the extension line of the side edge and the extension line of the bottom edge and facing towards the accommodation groove is equal to 90°, a distance between the side edge in the accommodation groove where the first color light-emitting unit is located and the first color light-emitting unit is greater than a distance between the side edge in the accommodation groove where the second color light-emitting unit is located and the second color light-emitting unit.

14. The display panel of claim 1, wherein
the array substrate comprises a light-transmissive region and a light-nontransmissive region, and the light-nontransmissive region comprises a driver circuit region;
the array substrate further comprises a TFT array layer located between the base substrate and the encapsulation layer, the TFT array layer in the driver circuit region comprises a drive transistor and a drive electrode, an end of the drive transistor is coupled to the drive electrode, and the drive electrode is exposed to a side surface of the TFT array layer facing away from the base substrate; and
a plurality of accommodation grooves are provided, the plurality of accommodation grooves comprise a first accommodation groove, the light-emitting unit is located in the first accommodation groove, the first accommodation groove is filled with the light-absorbing material, the light-emitting unit is electrically connected to the drive electrode, and a projection of the drive electrode on a plane where the base substrate is located is located in a projection of the first accommodation groove on the plane where the base substrate is located.

15. The display panel of claim 14, wherein
the TFT array layer in the driver circuit region comprises a height drop in a direction perpendicular to the base substrate and forms a first side wall;
at least a part of a projection of the first side wall on the plane where the base substrate is located is located in the projection of the first accommodation groove on the plane where the base substrate is located;
the plurality of accommodation grooves further comprise a second accommodation groove, and the second accommodation groove is filled with the light-absorbing material; and
the light-nontransmissive region further comprises a wire region, the TFT array layer in the wire region comprises at least one wire, and a projection of the at least one wire on the plane where the base substrate is located is located in a projection of the second accommodation groove on the plane where the base substrate is located.

16. A display device comprising a display panel, wherein the display panel comprises:
an array substrate comprising a base substrate and an encapsulation layer located on a side of the base substrate, wherein a side surface of the encapsulation layer facing away from the base substrate is provided with an accommodation groove; and
a light-emitting unit located in the accommodation groove, wherein the accommodation groove is filled with a light-absorbing material, a protective film is formed on both a side surface of the encapsulation layer facing away from the base substrate and a side surface of the light-emitting unit facing away from the base substrate, and an etching rate of the protective film is less than an etching rate of the light-absorbing material under a same etching condition.

17. A preparation method of a display panel, comprising:
preparing an array substrate, wherein the array substrate comprises a base substrate and an encapsulation layer located on a side of the base substrate, and a side surface of the encapsulation layer facing away from the base substrate is provided with an accommodation groove;
bonding a light-emitting unit into the accommodation groove;
forming a protective film on both a side surface of the encapsulation layer facing away from the base substrate and a side surface of the light-emitting unit facing away from the base substrate;
forming, on a side surface of the encapsulation layer on which the light-emitting unit is bonded facing away from the base substrate, a light-absorbing material layer to enable the accommodation groove to be filled with a light-absorbing material, wherein an etching rate of the protective film is less than an etching rate of the light-absorbing material under a same etching condition; and
patterning the light-absorbing material layer to remove the light-absorbing material on the side surface of the encapsulation layer facing away from the base substrate and the side surface of the light-emitting unit facing away from the base substrate.

18. The preparation method of claim 17, wherein preparing the array substrate comprises:
forming a thin film transistor (TFT) array layer on a side surface of the base substrate, wherein the array substrate comprises a light-transmissive region and a light-nontransmissive region, the light-nontransmissive region comprises a driver circuit region, the TFT array layer in the driver circuit region comprises a drive transistor, and the TFT array layer comprises a height drop in a direction perpendicular to the base substrate and forms a first side wall; and
preparing, on the base substrate on which the TFT array layer is formed, a light-shielding structure, wherein the light-shielding structure comprises a first light-shielding segment, and the first light-shielding segment covers at least a part of the first side wall of the TFT array layer.

19. The preparation method of claim 18, wherein the TFT array layer comprises a planarization layer;
wherein before preparing, on the base substrate on which the TFT array layer is formed, the light-shielding structure, the method further comprises:
forming a groove on a side surface of the planarization layer facing away from the base substrate, wherein the array substrate further comprises a transition region located between the driver circuit region and the light-transmissive region, a projection of the groove on a plane where the base substrate is located is located in the transition region, and the first side wall of the TFT array layer is also used as an inner wall of the groove; and
wherein preparing, on the base substrate on which the TFT array layer is formed, the light-shielding structure comprises:
coating, on the base substrate on which the TFT array layer is formed, the light-absorbing material, and filling the groove with at least a part of the light-absorbing material; and
curing the light-absorbing material to form the first light-shielding segment, wherein the groove is filled with a part of the first light-shielding segment.

20. The preparation method of claim 17, wherein the protective film is an inorganic protective film; and
wherein forming, on both the side surface of the encapsulation layer facing away from the base substrate and the side surface of the light-emitting unit facing away from the base substrate, the protective film comprises:
forming, by using an inorganic material, on both the side surface of the encapsulation layer facing away from the base substrate and the side surface of the light-emitting unit facing away from the base substrate, the inorganic protective film.
